(19) United States
(12) Patent Application Publication
(10) Pub. No.: US 2011/0007592 A1
(43) Pub. Date: Jan. 13, 2011

(54) Semiconductor storage device and refresh control method thereof

(75) Inventor: Shinya Tashiro, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kawasaki (JP)

(21) Appl. No.: 12/801,854

(22) Filed: Jun. 29, 2010

(30) Foreign Application Priority Data
Jul. 10, 2009 (JP) 2009-163901

(51) Int. Cl. G11C 7/00

(52) U.S. Cl. 365/222; 365/230.03

(57) ABSTRACT

In a large capacity semiconductor storage device having a multi-bank configuration, it is desired to reduce a peak current of one refresh operation, to avoid an interference between adjacent banks, and to prevent a data breaking of a memory cell caused by a lack of a data hold time. A semiconductor storage device includes: a memory cell array part including a plurality of banks; a refresh control circuit configured to output a refresh timing control signal periodically; and an access control circuit configured to perform a refresh operation on a group of banks which are not adjacent to one another in accordance with a preset combination of banks which are simultaneously activated and a preset activating order when the refresh timing control signal is supplied.

### INCORPORATION BY REFERENCE

This patent application is based on Japanese Patent Application No. 2009-163901. The disclosure of the Japanese Patent Application is incorporated herein by reference.

### BACKGROUND OF THE INVENTION

1. Field of the Invention

The present invention relates to a semiconductor storage device and a refresh control method of a semiconductor storage device.

2. Description of Related Art

In recent years, mobile devices represented by the mobile telephone include very many functions, and include a function for accessing WEB servers and displaying contents of websites on computer networks. In order to attain such functions, a large quantity of data received by the mobile device is required to be temporally stored in a semiconductor storage device inside the mobile device.

As this semiconductor storage device, the SRAM (Static Random Access Memory) is preferable from the viewpoints that the treatment is easy, the operation speed is high, and the electric power consumption is low. However, the DRAM (Dynamic Random Access Memory) is preferable from the viewpoint of the large memory capacity. Therefore, a device referred to as “the Pseudo SRAM,” having the merits of the SRAM and the DRAM, has become to be mounted as a semiconductor storage device on mobile devices.

In the pseudo SRAM, differently from the DRAM, the address is not required to be divided into the row address and the column address and separately supplied, and timing signals such as RAS and CAS are not required. In the pseudo SRAM, the address may be given only one time similarly to the general SRAM, and a chip enable signal corresponding to the clock of a semiconductor storage device of the clock synchronization type is used as a trigger, and the address can be captured, read and written therein. However, since the pseudo SRAM use the same memory cell as the DRAM, an autonomous refresh control is carried out such that written data can be guaranteed even in continuous writing and reading operations.

A feature of the pseudo SRAM lies in an operational specification that does not require a refresh command to be controlled from outside. However, in association with the popularization of various mobile telephone systems, a larger memory capacity, smaller electric power consumption and higher speed has been increasingly requested.

FIG. 1 is a block diagram showing a configuration of the pseudo SRAM described in Japanese Patent No. 4022392 (which is referred to as the Patent Document 1), as an example of conventional pseudo SRAMs.

The conventional pseudo SRAM contains an address buffer circuit 21, an address transition detection circuit (ATD circuit) 25, a row control circuit 26, a column control circuit 27, a memory cell array 30, a row decoder 31, a sense amplifier 33, a column decoder 35, an I/O buffer 36, a switch circuit (MUX1) 41, a switch circuit (MUX2) 42, a timer circuit 50, a test mode entry circuit 53, a refresh pulse generation circuit 60, a test refresh pulse generation circuit 62 and a refresh address generation circuit 66.

The address buffer circuit 21 inputs a reading/writing address signal Add from outside. The reading/writing address signal Add includes a column address data AddC and a row address data AddR. The address buffer circuit 21 outputs the reading/writing address signal Add to the ATD circuit 25, outputs the column address data AddC included in the reading/writing address signal Add to the column decoder 35 and outputs the row address data AddR included in the reading/writing address signal Add to the switch circuit (MUX2) 42.

The ATD circuit 25 inputs the reading/writing address signal Add outputted by the address buffer circuit 21. When at least one bit inside the reading/writing address signal Add is changed, the ATD circuit 25 detects the change in the reading/writing address signal Add and outputs an address transition detection signal ATD to the row control circuit 26 and the test refresh pulse generation circuit 62.

The row control circuit 26 inputs the address transition detection signal ATD outputted by the ATD circuit 25 and a refresh timing control signal RF outputted by the switch circuit (MUX1) 41 and generates a row enable signal RE, a sense enable signal SE and a column control signal CC. The row control circuit 26 outputs the row enable signal RE, the sense enable signal SE and the column control signal CC to the row decoder 31, the sense amplifier 33 and the column control circuit 27, respectively.

Here, the row enable signal RE is a pulse signal which rises in response to a trail of the address transition detection signal ATD and trails after a certain time (refer to FIG. 2). The sense enable signal SE is a signal in which the row enable signal RE is delayed by a certain time (refer to FIG. 2). The column control signal CC is a signal in which the pulse signal based on the trailing of the address transition detection signal ATD is delayed by a certain time (not shown).

The column control circuit 27 inputs the column control signal CC outputted by the row control circuit 26 and further delays the column control signal CC and then outputs signal CE to the column decoder 35 as a column enable.

The memory cell array 30 has a configuration similar to that of the memory cell array of a typical DRAM.

The row decoder 31 selectively activates a word line of the memory cell array 30, which corresponds to a row address MAdd outputted by the switch circuit (MUX2) 42, at a timing when the signal level (logical level) of the row enable signal RE outputted by the row control circuit 26 is switched to the HIGH level.

The sense amplifier 33 activates a bit line of the memory cell array 30, at a timing when the logical level of the sense enable signal SE outputted by the row control circuit 26 is switched to the HIGH level.

The column decoder 35 decodes the column address data AddC outputted by the address buffer circuit 21, at a timing when the logical level of the column enable signal CE outputted by the column control circuit 27 is switched to the HIGH level, and connects the sense amplifier based on the decoded result, through the I/O buffer 36 to an input/output data terminal 37.

The timer circuit 50 outputs a timing signal TM at a constant time interval.

The refresh pulse generation circuit 60 generates a signal of the refresh timing in a normal operation and inputs the timing signal TM outputted at a constant time interval by the timer circuit 50. The refresh pulse generation circuit 60 generates a normal refresh pulse signal REF in accordance with this timing signal TM and supplies to the switch circuit (MUX1) 41.

The test refresh pulse generation circuit 62 generates a test refresh pulse signal TREF1 for generating a test refresh timing in an operation check test in accordance with the address transition detection signal ATD outputted by the ATD circuit 25 and supplies to the switch circuit (MUX1) 41.

The test mode entry circuit 53 controls the switching action between the normal operation mode and the test mode from outside of the apparatus. The test mode entry circuit 53 generates an operation mode switch signal TE1 in accordance with a test mode entry signal TE given from outside and supplies to the switch circuit (MUX1) 41.

The switch circuit (MUX1) 41 switches the refresh timing on the basis of the operation mode (normal operation mode or test mode). The switch circuit (MUX1) 41 inputs the operation mode switch signal TE1 outputted by the test mode entry circuit 53, the normal refresh pulse signal REF outputted by the refresh pulse generation circuit 60, and the test refresh pulse signal TREF1 outputted by the test refresh pulse generation circuit 62 and generates the refresh timing control signal RF. The switch circuit (MUX1) 41 supplies this refresh timing control signal RF to the row control circuit 26, the refresh address generation circuit 66 and the switch circuit (MUX2) 42. In short, the switch circuit (MUX1) 41 outputs one of the signal of the timing control based on the normal refresh pulse signal REF and the signal of the timing control based on the test refresh pulse signal TREF1, as the timing control signal RF, in response to the operation mode switch signal TE1.

The refresh address generation circuit 66 uses the refresh timing control signal RF, which is outputted by the switch circuit (MUX1) 41 as a trigger to count up the refresh address and supplies it as a refresh address RAdd to the switch circuit (MUX2) 42.

The input of the switch circuit (MUX2) 42 is connected to an output of the address buffer circuit 21 and an output of the switch circuit (MUX1) 41. The switch circuit (MUX2) 42 inputs the row address data AddR outputted by the address buffer circuit 21, the refresh address RAdd outputted by the refresh address generation circuit 66, and the refresh timing control signal RF outputted by the switch circuit (MUX1) 41, and generates the row address MAdd for specifying the memory cell to be accessed, and then supplies to the row decoder 31. Specifically, when a self refresh operation is determined to be started in accordance with the logical level (0 or 1) of the refresh timing control signal RF, namely, when the logical level of the refresh timing control signal RF is switched froth the LOW level to the HIGH level, the switch circuit (MUX2) 42 outputs the refresh address RAdd as the row address MAdd, and in the case except it, outputs the row address data AddR as the row address MAdd.

FIG. 2 is a timing chart showing the operation of the pseudo SRAM in FIG. 1.

The normal operation mode will be described below. The test mode entry signal TE is set to the LOW level, and the operation mode switch signal TE1 outputted by the test mode entry circuit 53 is switched to the LOW level. When TE=0, namely, at the normal operation mode, the test circuit is not operated. Thus, the operation is same to the pseudo SRAM on which the test circuit is not mounted.

At first, the reading and writing operations at the normal operation mode are described.

At the time T1, when the reading/writing address signal Add is changed from “A0” to “A1”, the ATD circuit 25 detects the address change, raises the address transition detection signal ATD at the time T2 and supplies as a positive one shot pulse signal to the row control circuit 26 and the switch circuit (MUX2) 42. Here, the above addresses A0, A1 are supposed to be row addresses, and a case where only row group addresses are changed is explained.

Also, in association with the change in the reading/writing address signal Add, at the time T3, the row address MAdd is switched from “A0” to “A1”. At the time T3, the logical level of the refresh timing control signal RF that is the output signal of the switch circuit (MUX1) 41 is the LOW level. Thus, the switch circuit (MUX2) 42, since determining that the self refresh operation is not started, supplies the row address data AddR as the row address MAdd to the row decoder 31.

The row control circuit 26, when receiving the address transition detection signal ATD, uses the trailing edge of the address transition detection signal ATD at the time T4 as the trigger, and raises the row enable signal RE at the time T5, and supplies the row enable signal RE having a predetermined pulse length to the row decoder 31. At the time T5, the row address MAdd is inputted to the row decoder 31 from the switch circuit (MUX2) 42. Thus, at the time T6, the row decoder 31 activates a word line Word specified by the row address MAdd (AddR=A1), synchronously with the row enable signal RE.

The row control circuit 26 uses the trailing edge of the address transition detection signal ATD at the time T4 as the trigger and raises the sense enable signal SE at the time. T7 and supplies to the sense amplifier 33 and then activates the sense amplifier 33. Moreover, the row control circuit 26 uses the trailing edge of the address transition detection signal ATD at the time T4 as the trigger and raises the column control signal CC and supplies to the column control circuit 27. Then, at the time T8, the column control circuit 27 raises the column enable signal CE at the timing based on the column control signal CC (consequently, based on the row enable signal RE) and supplies to the column decoder 35. The column group address AddC is inputted to the column decoder 35.

The column decoder 35 receives the column enable signal CE, decodes the column address data AddC and connects the sense amplifier 33 based on the decoded result through the I/O buffer 36 to the input/output data terminal 37. When the normal operation mode indicates the reading operation, the data stored in the cell that is specified by the row address data AddR (A0) in the memory cell array 30 is outputted through the sense amplifier 33 and the I/O buffer 36 to the input/output data terminal 37. When the normal operation mode indicates the writing operation, the data of the input/output data terminal 37 is written to the cell specified by an address data A1 in the memory cell array 30.

After the elapse of a predetermined time from the trailing edge of the address transition detection signal ATD at the time T4, the row enable signal RE, the column enable signal CE and the column enable signal CE trails down. The explanation of reading and writing operations in the normal operation mode are completed here.

Next, the self refresh operation at the normal operation mode will be described below. The self refresh operation is the refresh operation started at a constant time interval, in accordance with the timing and address which are internally generated, independently of the signal inputted from outside of the apparatus.

The start timing of the self refresh operation is generated by the timer circuit 50. At the time T10, the timer circuit 50 outputs the timing signal TM having a predetermined pulse width. At this time, the refresh pulse generation circuit 60 outputs the normal refresh pulse signal REF, as a one shot pulse signal having the pulse width corresponding to the time required for one refresh operation, in accordance with the rising edge of this timing signal TM, and supplies to the switch circuit (MUX1) 41.

On the other hand, the refresh address RAdd is generated by the refresh address generation circuit 66. In the following description, it is assumed that at the time T10 when the signal TM is outputted, the refresh address generation circuit 66 generates “R0” as the refresh address RAdd and supplies it to the switch circuit (MUX2) 42.

The switch circuit (MUX1) 41 outputs the refresh timing control signal RF, in accordance with the normal refresh pulse signal REF, at the normal operation mode. The switch circuit (MUX2) 42 determines that the self refresh operation is started, in response to the rising of the refresh timing control signal RF having a slight delay from the time T10 and switches the row address MAdd to RAdd=R0.

At the time T11, the row control circuit 26 raises the row enable signal RE, in response to the rising of the refresh timing control signal RF. That is, the logical level of the row enable signal RE is switched to the HIGH level. The refresh address RAdd is supplied to the row decoder 31. Thus, at the time T12, the row decoder 31 activates the word line Word specified on the basis of RAdd=R0, synchronously with the row enable signal RE.

Moreover at the time T13, the sense enable signal SE rises, which activates the sense amplifier 33, and the memory cell connected to the above-activated word line Word is refreshed. As mentioned above, the refresh operation of the memory cell specified by the refresh address RAdd (R0) is completed.

At the time T14, when the refresh timing control signal RF falls down, the switch circuit (MUX2) 42 determines that the self refresh operation is finished and then switches the row address MAdd from a refresh address RAdd (R0) to a row address data AddR (A1). Further, the falling of the refresh timing control signal RF is supplied to the refresh address generation circuit 66. At this time, the refresh address generation circuit 66 uses the fall of the refresh timing control signal RF as a trigger to count up the refresh address RAdd and switches the refresh address RAdd to R1.

Moreover, at the time T15, when the reading/writing address signal Add is changed from (A1) to (A2), the row address data AddR is changed from (A1) to (A2) at the time T16. Then, at the times T18 to T20, the word line Word specified by the row address MAdd (AddR=A2) is activated, and the reading and writing operations at the normal operation mode are continued.

As explained above, the conventional pseudo SRAM includes a plurality of memory cells to which refresh operation is required, and an access control circuit that accesses the memory cell corresponding to an input address signal to carry out reading or writing, and the refresh of the simultaneous activation is performed to the address selected at the refresh timing, which is generated independently of the above accesses, at the normal operation mode.

### SUMMARY

If a conventional pseudo SRAM constructed by a plurality of banks is applied in a case of a pseudo SRAM having a large memory capacity, there is a problem that a lack of data hold time of the memory cell causes the memory cell data to be broken. This is caused by the following operation. In the conventional pseudo SRAM, in the read and write operation and the standby state, interrupting refresh operation is performed in response to a request from a timer circuit, and only one time interrupting refresh operation is performed and completed. And in the refresh operation, selected word lines are always simultaneously activated.

In the pseudo SRAM whose capacity is made large by employing a configuration with many banks, to simultaneous activate on a basis of a method as a conventional SRAM, it is required to simultaneously activating many adjacent banks. Therefore, the peak current increases so that the load on the current capacity of an internal power source system circuit and the GND increases. Moreover, caused by the neighboring arrangement of the layout, mutual interferences, such as a drop in an internal power source and floating of a GND connected to the memory cell array. For this reason, in a sense amplifier connected to the memory cell array, the supply of the level sufficient for the driving signal is prevented. As a result, the activating operation is delayed, and the potential of a Digit (bit line) pair is prevented from being made wide within the activation time of the word. Also, the holding level of the memory cell data is decreased, which results in a problem that the data hold time of the memory cell is lacked and the data in the memory cell is broken.

Further, the pseudo SRAM described in Japanese Patent Application Publication JP-P 2002-093164A (which is referred to as the Patent Document 2 has the same problem. The reason and ground of the occurrence of the problem is same to those of the above pseudo SRAM (the pseudo SRAM described in Japanese Patent No. 4022392).

The means to solve the subjects will be described below by using the symbols (with parentheses) used in the embodiment of the present invention. These symbols are added to clarify the correspondence between the descriptions in claims and the descriptions in the embodiment for carrying out the present invention, and they should not be used to construe the technical range of the present invention described in claims.

According to an aspect of the present invention, a semiconductor storage device includes: a memory cell array part including a plurality of banks; a refresh control circuit configured to output a refresh timing control signal periodically; and an access control circuit configured to perform a refresh operation on a group of banks which are not adjacent to one another in accordance with a preset combination of banks which are simultaneously activated and a preset activating order when the refresh timing control signal is supplied.

In a configuration of the present invention, in a semiconductor storage device whose capacity is made large by employing the many-bank configuration, the refresh operation is performed on a group of bank which are not adjacent to one another, in accordance with the combination of the bank simultaneous activation (the combination of banks being simultaneously activated) and the activating order. Thus, the interference of the adjacent banks can be avoided while the peak current in one refresh operation is decreased over the conventional technique. Further, the lack of the data hold time of the memory cell is solved, so that the data break in the memory cell that is caused by the lack of the data hold time can be prevented.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a block diagram showing the configuration of the pseudo SRAM described in Japanese Patent No. 4022392 as a conventional pseudo SRAM;

FIG. 2 is a timing chart showing an operation of the conventional pseudo SRAM;

FIG. 3 is a block diagram showing a configuration of the pseudo SRAM according to a first embodiment of the present invention;

FIG. 4A shows a configuration of a memory cell array unit in the pseudo SRAM according to the first and second embodiments of the present invention;

FIG. 4B shows a configuration of the memory cell array unit in the pseudo SRAM according to the first and second embodiments of the present invention;

FIG. 5 shows a configuration of the row control circuit in FIG. 3;

FIG. 6 shows a configuration of the standby refresh division circuit in FIG. 5;

FIG. 7 shows a configuration of the interruption refresh determination circuit in FIG. 5;

FIG. 8 shows a configuration of the internal refresh division circuit in FIG. 5;

FIG. 9 shows a configuration of the bank activation allocation circuit in FIG. 5;

FIG. 10A is a timing chart showing an operation in the pseudo SRAM according to the first embodiment of the present invention;

FIG. 10B is a timing chart showing an operation in the pseudo SRAM according to the first embodiment of the present invention;

FIG. 10C is a timing chart showing an operation in the pseudo SRAM according to the first embodiment of the present invention;

FIG. 11 is a block diagram showing a configuration of the pseudo SRAM according to the second embodiment of the present invention;

FIG. 12 shows a configuration of the row control circuit in FIG. 11;

FIG. 13 shows a configuration of the bank activation allocation circuit in FIG. 12;

FIG. 14 shows a state chart of the bank activation allocation circuit in the pseudo SRAM according to the second embodiment of the present invention;

FIG. 15A is a timing chart showing an operation in the pseudo SRAM according to the second embodiment of the present invention;

FIG. 15B is a timing chart showing an operation in the pseudo SRAM according to the second embodiment of the present invention;

FIG. 15C is a timing chart showing an operation in the pseudo SRAM according to the second embodiment of the present invention;

FIG. 16 shows the combination of the bank simultaneous activations and the activating order, in the pseudo SRAM according to the first embodiment of the present invention; and

FIG. 17 shows the combination of the bank simultaneous activations and the activating order, in the pseudo SRAM according to the second embodiment of the present invention.

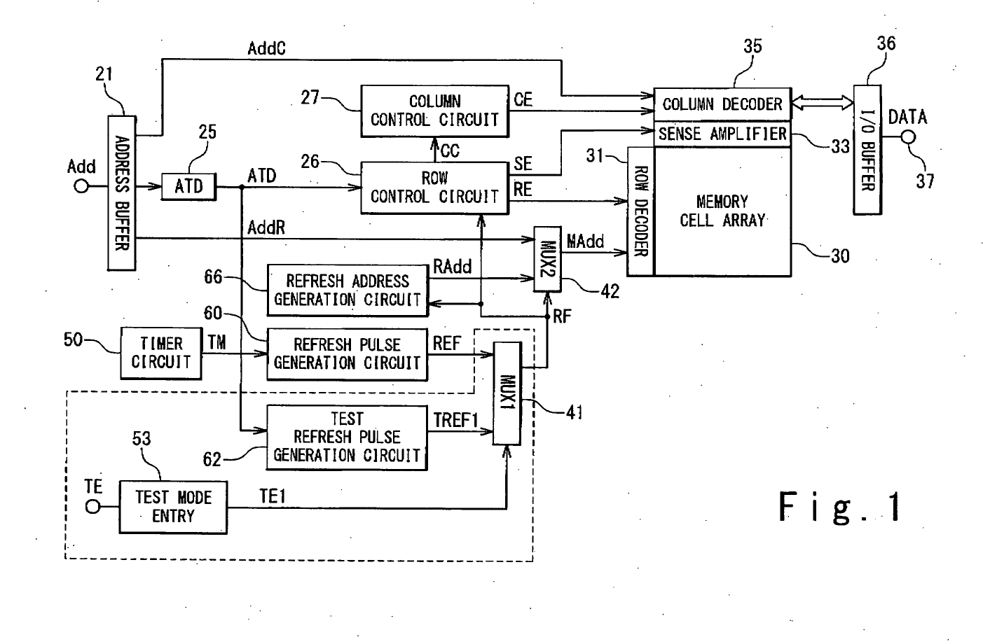

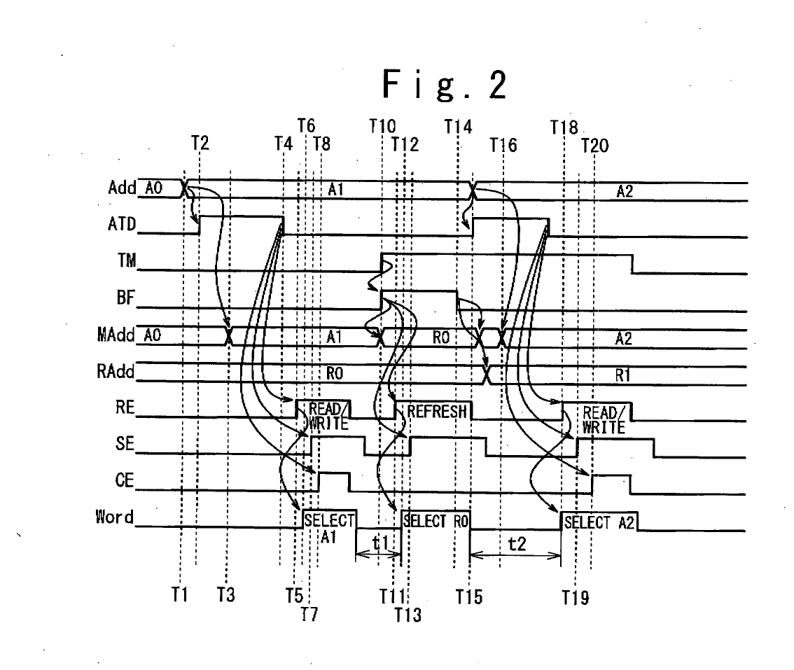

### DESCRIPTION OF THE PREFERRED EMBODIMENTS

In the following, pseudo SRAMs (Static Random Access Memory) will be described as semiconductor storage devices according to some exemplary embodiments of the present invention.

### First Embodiment

### Configuration

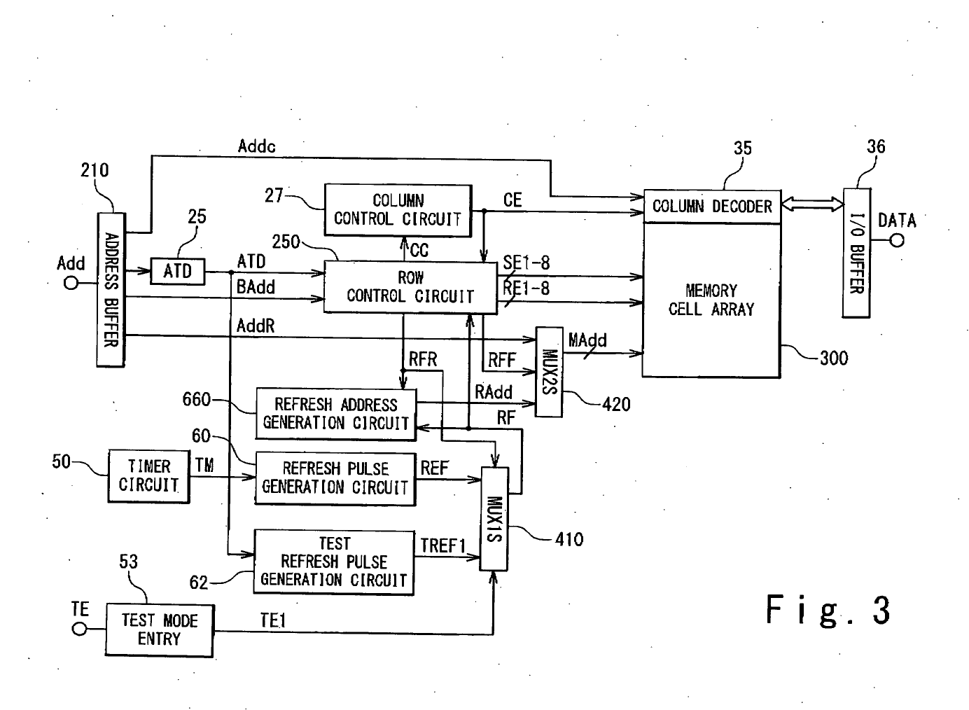

FIG. 3 is a block diagram showing a configuration of the pseudo SRAM according to a first embodiment of the present invention

The pseudo SRAM according to the first embodiment of the present invention contains a memory cell array unit 300, refresh control circuits (410, 50, 53, 60, 62 and 660) and access control circuits (210, 25, 250, 27, 35, 36 and 420). The memory cell array unit 300 contains a plurality of banks. The refresh control circuits (410, 50, 53, 60, 62 and 660) periodically output a refresh timing control signal RF. The access control circuits (210, 25, 250, 27, 35, 36 and 420) perform a self refresh operation (hereafter, referred to as the refresh operation) on non-adjacent bank groups, among the plurality of banks, in accordance with the combination of preset bank simultaneous activations and an activating order, when a refresh timing control signal RF is supplied.

The refresh control circuits (410, 50, 53, 60, 62 and 660) contain a switch circuit (MUX1S) 410, a timer circuit 50, a test mode entry circuit 53, a refresh pulse generation circuit 60, a test refresh pulse generation circuit 62 and a refresh address generation circuit 660.

The access control circuits (210, 25, 250, 27, 35, 36 and 420) contain an address buffer circuit 210, an address transition detection circuit (the ATD circuit) 25, a row control circuit 250, a column control circuit 27, a column decoder 35, an I/O buffer 36 and a switch circuit (MUX2S) 420.

That is, the pseudo SRAM according to the first embodiment of the present invention contains the address buffer circuit 210, the row control circuit 250, the switch circuit (MUX1S) 410, the switch circuit (MUX2S) 420 and the refresh address generation circuit 660, instead of the address buffer circuit 21, the row control circuit 26, the switch circuit (MUX1) 41, the switch circuit (MUX2) 42 and the refresh address generation circuit 66 in the conventional pseudo SRAM, respectively. Also, the pseudo SRAM according to the first embodiment of the present invention contains the memory cell array unit 300, instead of the memory cell array 30, the row decoder 31 and the sense amplifier 33 in the conventional pseudo SRAM.

Here, in the present invention, the descriptions overlapping with those of the conventional pseudo SRAM are omitted.

The address buffer circuit 210 inputs reading/writing address Add from outside. The reading/writing address signal Add includes a column address data AddC, a row address data AddR and a bank address data BAdd allocated to the bank of the memory cell array unit 300. The address buffer circuit 210 outputs the reading/writing address signal Add to the ATD circuit 25, outputs the column address data AddC included in the reading/writing address signal Add to the column decoder 35 and outputs the row address data AddR included in the reading/writing address signal Add to the switch circuit (MUX2S) 420 and outputs the bank address data BAdd to the row control circuit 250.

The row control circuit 250 inputs the address transition detection signal ATD outputted by the ATD circuit 25, the bank address data BAdd outputted by the address buffer circuit 210, the refresh timing control signal RF outputted by the switch circuit (MUX1S) 410, and the column enable signal CE outputted by the column control circuit 27, and outputs the row address enable signals RE1 to RE8 and the sense enable signals SE1 to SE8 to the memory cell array unit 300, outputs the column control signal CC to the column control circuit 27, and outputs a refresh frequency counter reset signal RFR to the refresh address generation circuit 660 and the switch circuit (MUX1S) 410, and outputs an interruption refresh signal RFF to the switch circuit (MUX2S) 420.

The refresh address generation circuit 660 inputs the refresh frequency counter reset signal RFR outputted by the row control circuit 250 and the refresh timing control signal RF outputted by the switch circuit (MUX1S) 410 and outputs the refresh address RAdd to the switch circuit (MUX2S) 420.

The switch circuit (MUX1S) 410 inputs a normal refresh pulse signal REF outputted by the refresh pulse generation circuit 60, a test refresh pulse signal TREF1 outputted by the test refresh pulse generation circuit 62, the refresh frequency counter reset signal RFR outputted by the row control circuit 250, and an operation mode switch signal TE1 outputted by the test mode entry circuit 53 and outputs the refresh timing control signal RF to the refresh address generation circuit 660 and the row control circuit 250.

The switch circuit (MUX2S) 420 inputs the row address data AddR outputted by the address buffer circuit 210, the interruption refresh signal RFF outputted by the row control circuit 250, and the refresh address RAdd outputted by the refresh address generation circuit 660 and outputs a row address MAdd at the time of the interruption refresh to the memory cell array unit 300.

The ATD circuit 25, the timer circuit 50, the test mode entry circuit 53, the column control circuit 27, the refresh pulse generation circuit 60 and the test refresh pulse generation circuit 62 are same to those of the aforementioned conventional pseudo SRAM.

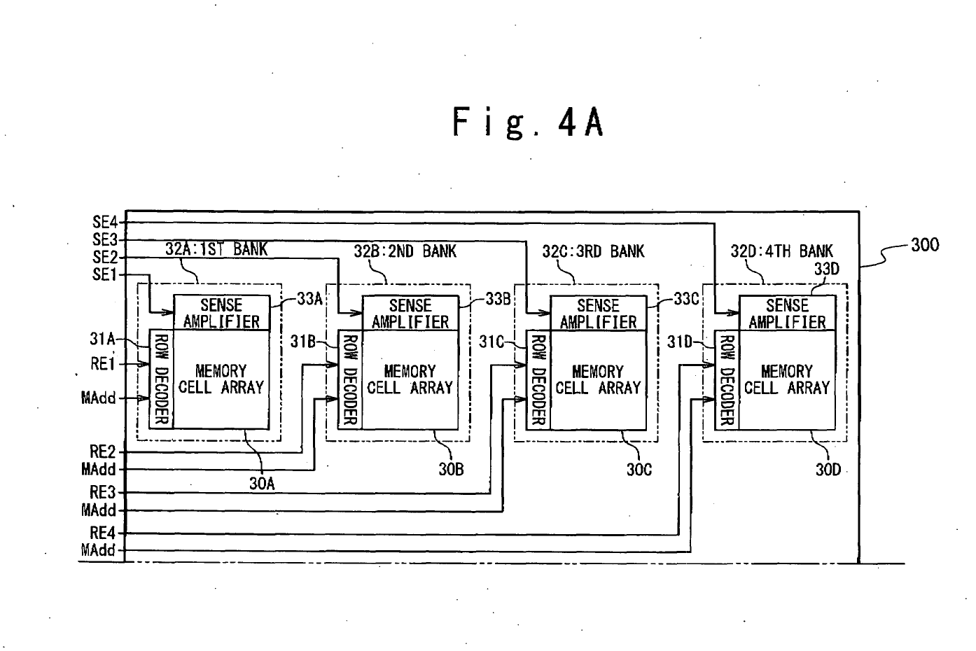

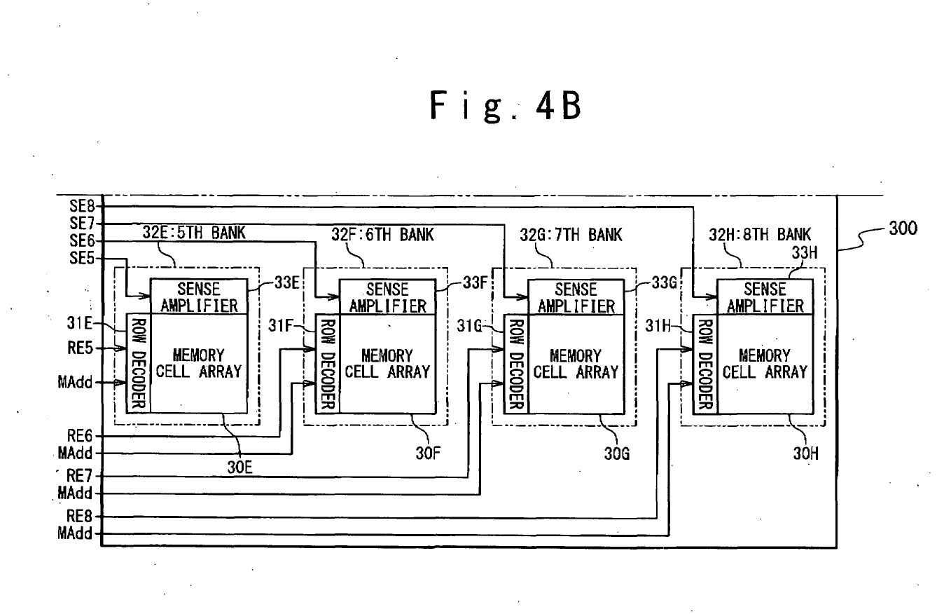

FIGS. 4A and 4B show the configuration of the memory cell array unit 300.

The memory cell array unit 300 contains the (M×N) banks, which are arrayed in M rows N columns (M and N are the integers of 2 or more, and the M×N is an even number). When M and N are assumed to be 2 and 4, respectively, its 8-bank configuration is referred to as banks 32A to 32H. It is supposed that the banks 32A to 32D are arranged at the first to fourth columns on the first row, respectively, and the fifth to eighth banks 32E to 32H are arranged at the first to fourth columns on the second row, respectively.

The bank 32A contains a memory cell array 30A, a row decoder 31A and a sense amplifier 33A. The row decoder 31A selectively activates the word line of the memory cell array 30A that corresponds to the row address MAdd outputted by the switch circuit (MUX2S) 420, at a timing when the signal level (logical level) of the row address enable signal RE1 outputted by the row control circuit 250 is switched to the HIGH level. The sense amplifier 33A activates the bit line of the memory cell array 30A, at a timing when the logical level of the sense enable signal SE1 outputted by the row control circuit 250 is switched to the HIGH level.

The bank 32B contains a memory cell array 30B, a row decoder 31B and a sense amplifier 33B. The row decoder 31B selectively activates the word line of the memory cell array 30B that corresponds to the row address MAdd outputted by the switch circuit (MUX2S) 420, at a timing when the logical level of the row address enable signal RE2 outputted by the row control circuit 250 is switched to the HIGH level. The sense amplifier 33B activates the bit line of the memory cell array 30B, at a timing when the logical level of the sense enable signal SE2 outputted by the row control circuit 250 is switched to the HIGH level.

The bank 32C contains a memory cell array 30C, a row decoder 31C and a sense amplifier 33C. The row decoder 31C selectively activates the word line of the memory cell array 30C that corresponds to the row address MAdd outputted by the switch circuit (MUX2S) 420, at a timing when the logical level of the row address enable signal RE3 outputted by the row control circuit 250 is switched to the HIGH level. The sense amplifier 33C activates the bit line of the memory cell array 30C, at a timing when the logical level of the sense enable signal SE3 outputted by the row control circuit 250 is switched to the HIGH level.

The bank 32D contains a memory cell array 30D, a row decoder 31D and a sense amplifier 33D. The row decoder 31D selectively activates the word line of the memory cell array 30D that corresponds to the row address MAdd outputted by the switch circuit (MUX2S) 420, at a timing when the logical level of the row address enable signal RE4 outputted by the row control circuit 250 is switched to the HIGH level. The sense amplifier 33D activates the bit line of the memory cell array 30D, at a timing when the logical level of the sense enable signal SE4 outputted by the row control circuit 250 is switched to the HIGH level.

The bank 32E contains a memory cell array 30E, a row decoder 31E and a sense amplifier 33E. The row decoder 31E selectively activates the word line of the memory cell array 30E that corresponds to the row address MAdd outputted by the switch circuit (MUX2S) 420, at a timing when the logical level of the row address enable signal RE5 outputted by the row control circuit 250 is switched to the HIGH level. The sense amplifier 33E activates the bit line of the memory cell array 30E, at a timing when the logical level of the sense enable signal SE5 outputted by the row control circuit 250 is switched to the HIGH level.

The bank 32F contains a memory cell array 30F, a row decoder 31F and a sense amplifier 33F. The row decoder 31F selectively activates the word line of the memory cell array 30F that corresponds to the row address MAdd outputted by the switch circuit (MUX2S) 420, at a timing when the logical level of the row address enable signal RE6 outputted by the row control circuit 250 is switched to the HIGH level. The sense amplifier 33F activates the bit line of the memory cell array 30F, at a timing when the logical level of the sense enable signal SE6 outputted by the row control circuit 250 is switched to the HIGH level.

The bank 32G contains a memory cell array 30G, a row decoder 31G and a sense amplifier 33G. The row decoder 31G selectively activates the word line of the memory cell array 30G that corresponds to the row address MAdd outputted by the switch circuit (MUX2S) 420, at a timing when the logical level of the row address enable signal RE7 outputted by the row control circuit 250 is switched to the HIGH level. The sense amplifier 33G activates the bit line of the memory cell array 30G, at a timing when the logical level of the sense enable signal SE7 outputted by the row control circuit 250 is switched to the HIGH level.

The bank 32H contains a memory cell array 30H, a row decoder 31H and a sense amplifier 33H. The row decoder 31H selectively activates the word line of the memory cell array 30H that corresponds to the row address MAdd outputted by the switch circuit (MUX2S) 420, at a timing when the logical level of the row address enable signal RE8 outputted by the row control circuit 250 is switched to the HIGH level. The sense amplifier 33H activates the bit line of the memory cell array 30H, at a timing when the logical level of the sense enable signal SE8 outputted by the row control circuit 250 is switched to the HIGH level.

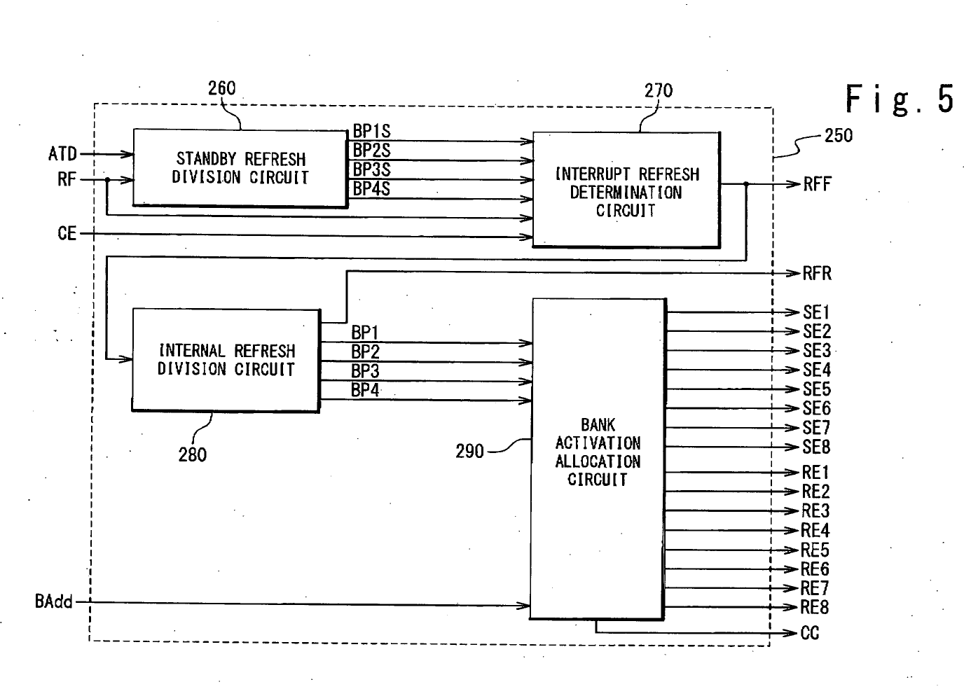

FIG. 5 shows the configuration of the row control circuit 250 shown in FIG. 3.

The row control circuit 250 contains a standby refresh division circuit 260, an interruption refresh determination circuit 270, an internal refresh division circuit 280 and a bank activation allocation circuit 290.

The standby refresh division circuit 260 inputs the refresh timing control signal RF outputted by the switch circuit (MUX1S) 410 and the address transition detection signal ATD outputted by the ATD circuit 25 and outputs standby refresh control signals BP1S to BP4S to the interruption refresh determination circuit 270.

The interruption refresh determination circuit 270 inputs the standby refresh control signals BP1S to BP4S outputted by the standby refresh division circuit 260, the refresh timing control signal RF outputted by the switch circuit (MUX1S) 410, and the column enable signal CS outputted by the column control circuit 27 and outputs the interruption refresh signal RFF to the internal refresh division circuit 280 and the switch circuit (MUX2S) 420.

The internal refresh division circuit 280 inputs the interruption refresh signal RFF outputted by the interruption refresh determination circuit 270 and outputs refresh activation one shot signals BP1 to BP4 to the bank activation allocation circuit 290 and outputs the refresh frequency counter reset signal RFR to the switch circuit (MUX1S) 410 and the refresh address generation circuit 660.

The bank activation allocation circuit 290 inputs the refresh activation one shot signals BP1 to BP4 outputted by the internal refresh division circuit 280 and the bank address data BAdd outputted by the address buffer circuit 210 and outputs the row address enable signals RE1 to RE8 and the sense enable signals SE1 to SE8 to the memory cell array unit 300.

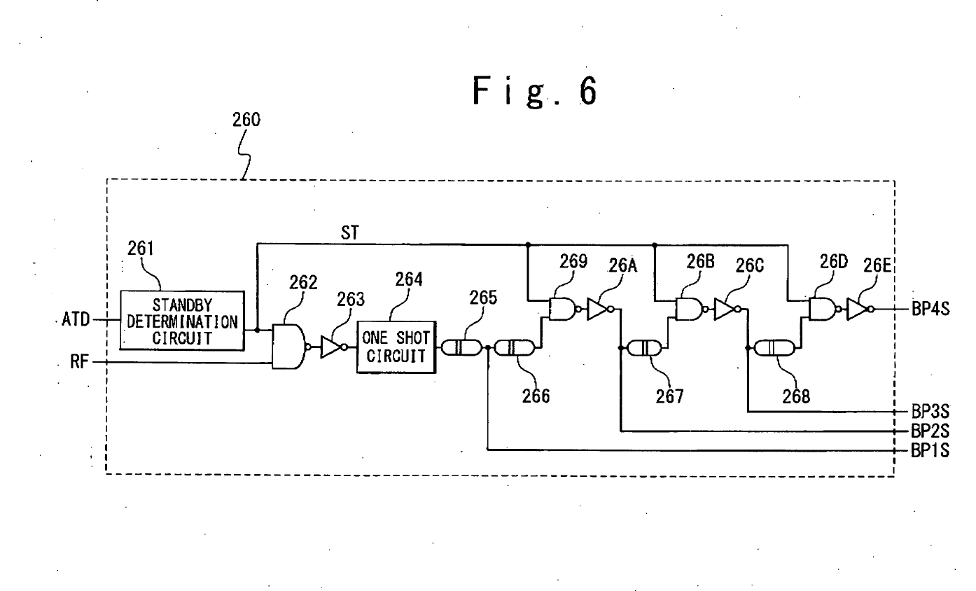

FIG. 6 shows the configuration of the standby refresh division circuit 260 in FIG. 5.

The standby refresh division circuit 260 contains a standby determination circuit 261, a NAND circuit 262, an inverter 263, a delay element 264, delay elements 265 to 268, a NAND circuit 269, an inverter 26A, a NAND circuit 26B, an inverter 26C, a NAND circuit 26D and an inverter 26E.

The input of the standby determination circuit 261 is connected to the output of the ATD circuit 25. The standby determination circuit 261 determines whether or not a transition of the reading/writing address signal Add occurs within any time. The standby determination circuit 261 inputs the address transition detection signal ATD outputted by the ATD circuit 25 and outputs a standby determination signal ST indicating the result of the determination.

An input of the NAND circuit 262 is connected to the output of the standby determination circuit 261. The NAND circuit inputs the standby determination signal ST outputted by the standby determination circuit 261. Another input of the NAND circuit 262 is connected to the output of the switch circuit (MUX1S) 410. The NAND circuit inputs the refresh timing control signal RF outputted by the switch circuit (MUX1S) 410.

The input of the inverter 263 is connected to the output of the NAND circuit 262. The input of the delay element 264 is connected to the output of the inverter 263. The delay elements 264, 265 adjust the refresh activation time of the standby state. In the delay element 265, its input is connected to the output of the delay element 264, and its output is supplied as the standby refresh control signal BP1S to the interruption refresh determination circuit 270.

The input of the delay element 266 is connected to the output of the delay element 265. In the NAND circuit 269, its input is connected to the output of the standby determination circuit 261 and inputs the standby determination signal ST outputted by the standby determination circuit 261. In the NAND circuit 269, its input is connected to the output of the delay element 266. In the inverter 26A, its input is connected to the output of the NAND circuit 269, and its output is supplied as the standby refresh control signal BP2S to the interruption refresh determination circuit 270.

The input of the delay element 267 is connected to the output of the inverter 26A. In the NAND circuit 26B, its input is connected to the output of the standby determination circuit 261 and inputs the standby determination signal ST outputted by the standby determination circuit 261. In the NAND circuit 26B, its input is connected to the output of the delay element 267. In the inverter 26C, its input is connected to the output of the NAND circuit 26B, and its output is supplied as the standby refresh control signal BP3S to the interruption refresh determination circuit 270.

The input of the delay element 268 is connected to the output of the inverter 26C. In the NAND circuit 26D, its input is connected to the output of the standby determination circuit 261 and inputs the standby determination signal ST outputted by the standby determination circuit 261. In the NAND circuit 26D, its input is connected to the output of the delay element 268. In the inverter 26E, its input is connected to the output of the NAND circuit 26D, and its output is supplied as the standby refresh control signal BP4S to the interruption refresh determination circuit 270.

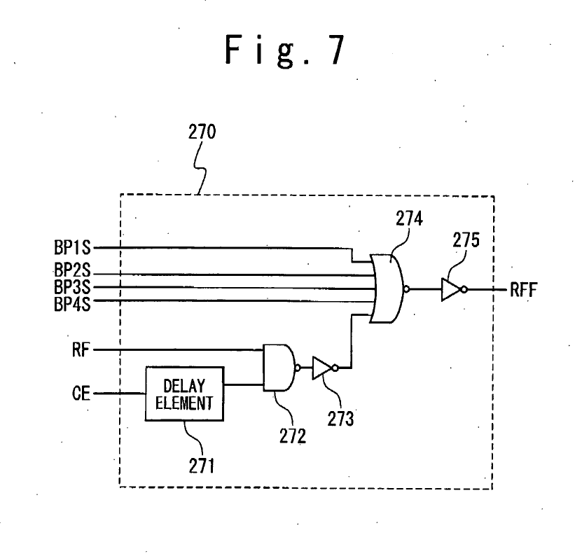

FIG. 7 shows the configuration of the interruption refresh determination circuit 270 in FIG. 5.

The interruption refresh determination circuit 270 contains a delay element 271, a NAND circuit 272, an inverter 273, a NOR circuit 274 and an inverter 275.

In the delay element 271, its input is connected to the output of the column control circuit 27 and inputs the column enable signal CE outputted by the column control circuit 27. The delay element 271 adjusts the determination times of the refresh timing control signal RF and the column enable signal CE. In the NAND circuit 272, its input is connected to the output of the switch circuit (MUX1S) 410 and inputs the refresh timing control signal RF outputted by the switch circuit (MUX1S) 410. In the NAND circuit 272, its input is connected to the output of the delay element 271. In the inverter 273, its input is connected to the output of the NAND circuit 272.

In the NOR circuit 274, its inputs are connected to the outputs of the standby refresh division circuit 260 and input the standby refresh control signals BP1S to BP4S outputted by the standby refresh division circuit 260, respectively. In the NOR circuit 274, its input is connected to the output of the inverter 273. In the inverter 275, its input is connected to the output of the NOR circuit 274, and its output is supplied as the interruption refresh signal RFF to the internal refresh division circuit 280 and the switch circuit (MUX2S) 420.

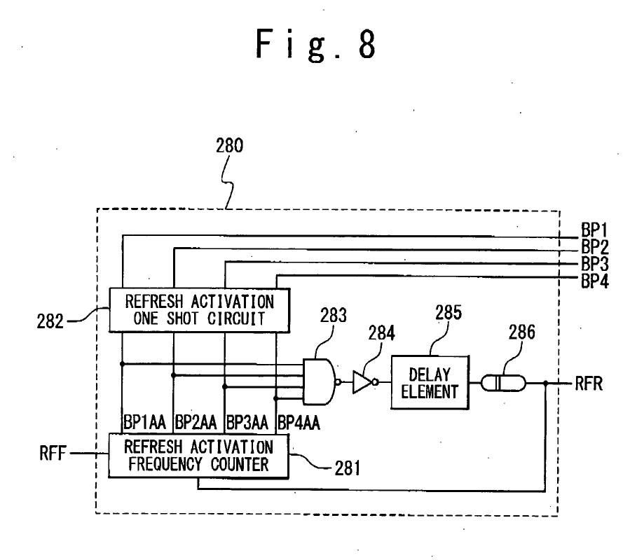

FIG. 8 shows the configuration of the internal refresh division circuit 280 in FIG. 5.

The internal refresh division circuit 280 contains a refresh activation frequency counter 281, a refresh activation one shot circuit 282, a NAND circuit 283, an inverter 284, a delay element 285 and a delay element 286.

The refresh activation frequency counter 281 counts the frequency of the activations of the interruption refresh signal RFF. In the refresh activation frequency counter 281, its input is connected to the output of the interruption refresh determination circuit 270 and inputs the interruption refresh signal RFF outputted by the interruption refresh determination circuit 270. The refresh activation frequency counter 281 sets the logical levels of a refresh frequency signal BP1AA indicating a count “1”, a refresh frequency signal BP2AA indicating a count “2”, a refresh frequency signal BP3AA indicating a count “3”, and a refresh frequency signal BP4AA indicating a count “4”, in this order, as the frequency of the refresh executions, to the HIGH level, on the basis of the interruption refresh signal RFF, and outputs the refresh activation one shot circuit 282 and the NAND circuit 283. The refresh activation frequency counter 281 whose input is connected to the output of the delay element 286 sets the logical levels of the refresh frequency signals BP1AA to BP4AA to the LOW level, at the same time, in order to reset the count, on the basis of the refresh frequency counter reset signal RFR outputted by the delay, element 286.

The refresh activation one shot circuit 282 whose inputs are connected to the outputs of the refresh activation frequency counter 281 and inputs the refresh frequency signals BP1AA to BP4AA outputted by the refresh activation frequency counter 281. When the logical levels of the refresh frequency signals BP1AA to BP4AA are H in this order, the refresh activation one shot circuit 282 outputs a refresh activation one shot signal BP1 indicating a first order, a refresh activation one shot signal BP2 indicating a second order, a refresh activation one shot signal BP3 indicating a third order and a refresh activation one shot signal BP4 indicating a fourth order, respectively, as the time necessary for the refresh activation of the memory cell array unit 300 and the activating order, to the bank activation allocation circuit 290.

The NAND circuit 283 whose input is connected to the output of the refresh activation frequency counter 281 inputs the refresh frequency signals BP1AA to BP4AA outputted by the refresh activation frequency counter 281. The input of the inverter 284 is connected to the output of the NAND circuit 283. The input of the delay element 285 is connected to the output of the inverter 284. The delay elements 285 286 adjust the time when the refresh activation frequency counter 281 is reset. In the delay element 286, its input is connected to the output of the delay element 285, and its output is supplied as the refresh frequency counter reset signal RFR to the refresh activation frequency counter 281 and the bank activation allocation circuit 290. The refresh frequency counter reset signal RFR indicates the completion of the refresh operations of all the banks.

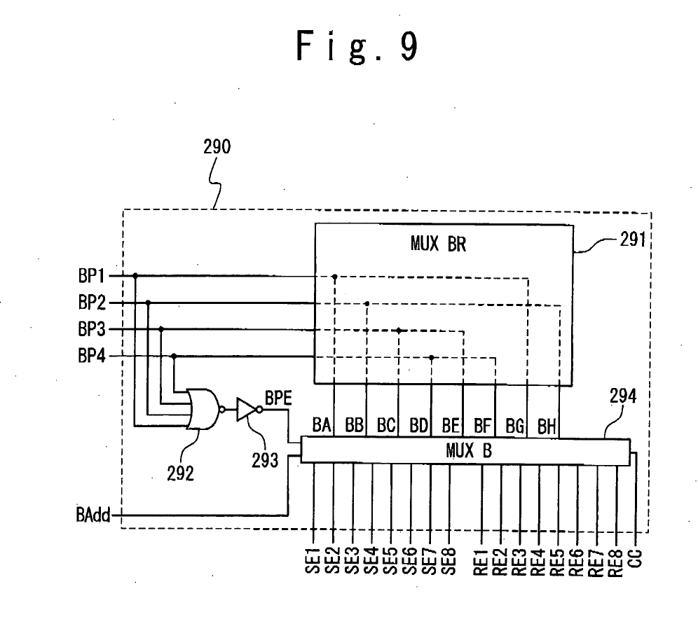

FIG. 9 shows the configuration of the bank activation allocation circuit 290.

The bank activation allocation circuit 290 attains a 2-bank simultaneous activation in which an autonomous refresh operation is arbitrarily set. This bank activation allocation circuit 290 contains a refresh bank switch circuit (MUXBR) 291, an NOR circuit 292, an inverter 293 and a bank enable switch circuit (MUXB) 294.

The refresh bank switch circuit (MUXBR) 291 whose inputs are connected to the outputs of the internal refresh division circuit 280 inputs the refresh activation one shot signals BP1 to BP4 that are outputted in turn from the internal refresh division circuit 280. The refresh bank switch circuit (MUXBR) 291 outputs refresh bank control signals BA to BH, which correspond to the bank addresses of the memory cell array unit 300, as a combination which will be described later, to the bank enable switch circuit (MUXB) 294, on the basis of the refresh activation one shot signals BP1 to BP4.

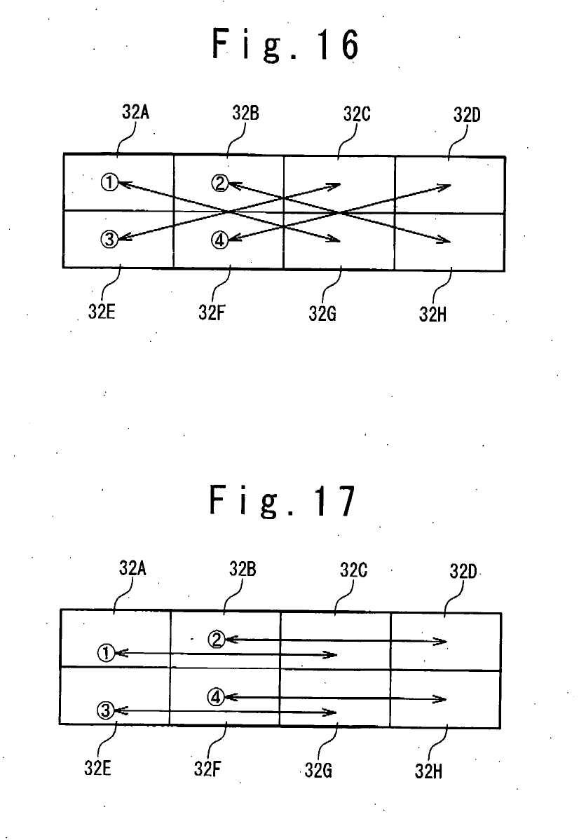

FIG. 16 shows the combinations of the bank simultaneous activations and the activating order, in the pseudo SRAM according to the first embodiment of the present invention. The numbers 1 to 4 in the respective circles indicate the 1st, 2nd, 3rd, and 4th combinations, respectively.

As shown in FIG. 16, the combination of the bank simultaneous activations and the activating order can be arbitrarily set. The combination of the bank simultaneous activations is set to avoid the simultaneous activation of the adjacent banks. Also, the refreshing order of the above combinations can be determined in order to carry out the interruption while allocating to the writing/reading operation and the standby state.

Some examples of the combination of the bank simultaneous activations and the activating order are provided below. In the refresh bank switch circuit (MUXBR) 291, with regard to the banks 32A to 32H in the M rows N columns, the bank group (X banks) as the combination of the bank simultaneous activations is allocated as Y groups composed of the first to Y-th groups (X, Y are the integers of two or more that satisfy X×Y=M×N) as the activating order. In this case, the X and the Y are assumed to be 2 and 4, respectively. As mentioned above, the M and the N are 2 and 4, respectively. The banks 32A to 32D are arranged at the first to fourth columns on the first row, respectively, and the fifth to eighth banks 32E to 32H are arranged at the first to fourth columns on the second row, respectively. In this case, in order to avoid the simultaneous activation of adjacent banks, the activating order is defined such as the banks 32A, 32G in the first group, the banks 32B, 32H in the second group, the banks 32C, 32E in the third group, and the banks 32D, 32F in the fourth group.

As the above combination, the refresh bank switch circuit (MUXBR) 291 outputs the refresh bank control signals BA, BG to the bank enable switch circuit (MUXB) 294, on the basis of the refresh activation one shot signal BP1. The refresh bank switch circuit (MUXBR) 291 outputs the refresh bank control signals BB, BH to the bank enable switch circuit (MUXB) 294, on the basis of the refresh activation one shot signal BP2. The refresh bank switch circuit (MUXBR) 291 outputs the refresh bank control signals BC BE to the bank enable switch circuit (MUXB) 294, on the basis of the refresh activation one shot signal BP3. The refresh bank switch circuit (MUXBR) 291 outputs the refresh bank control signals BD BF to the bank enable switch circuit (MUXB) 294, on the basis of the refresh activation one shot signal BP4.

The NOR circuit 292 whose inputs are connected to the outputs of the internal refresh division circuit 280 inputs the refresh activation one shot signals BP1 to BP4 that are outputted in turn from the internal refresh division circuit 280. In the inverter 293, its input is connected to the output of the NOR circuit 292, and its output is supplied as a division refresh enable signal BPE to the bank enable switch circuit (MUXB) 294.

The bank enable switch circuit (MUXB) 294 inputs the division refresh enable signal BPE outputted by the inverter 293, the bank address data BAdd outputted by the address buffer circuit 210, and the refresh bank control signals BA to BH outputted by the refresh bank switch circuit (MUXBR) 291 and outputs the sense enable signals SE1 to SE8 and the row address enable signals RE1 to RE8.

Specifically, assuming that the bank enable switch circuit (MUXB) 294 inputs the first and seventh refresh bank control signals BA, BG, in this case, the bank enable switch circuit (MUXB) 294 outputs the row address enable signal RE1 and the sense enable signal SE1 to the row decoder 31A of the bank 32A corresponding to the bank address data BAdd and the sense amplifier 33A, respectively, on the basis of the division refresh enable signal BPE and the refresh bank control signal BA. Simultaneously, the bank enable switch circuit (MUXB) 294 outputs the row address enable signal RE7 and the sense enable signal SE7 to the row decoder 31G of the bank 32G corresponding to the bank address data BAdd and the sense amplifier 33G, respectively, on the basis of the division refresh enable signal BPE and the refresh bank control signal BG.

It is assumed that the bank enable switch circuit (MUXB) 294 inputs the second and eighth refresh bank control signals BB, BH. In this case, the bank enable switch circuit (MUXB) 294 outputs the row address enable signal RE2 and the sense enable signal SE2 to the row decoder 31B of the bank 32B corresponding to the bank address data BAdd and the sense amplifier 33B, respectively, on the basis of the division refresh enable signal BPE and the refresh bank control signal BB. Simultaneously, the bank enable switch circuit (MUXB) 294 outputs the row address enable signal RE8 and the sense enable signal SE8 to the row decoder 31H of the bank 32H corresponding to the bank address data BAdd and the sense amplifier 33H, respectively, on the basis of the division refresh enable signal BPE and the refresh bank control signal BH.

It is assumed that the bank enable switch circuit (MUXB) 294 inputs the third and fifth refresh bank control signals BC, BE. In this case, the bank enable switch circuit (MUXB) 294 outputs the row address enable signal RE3 and the sense enable signal SE3 to the row decoder 31C of the bank 32C corresponding to the bank address data BAdd and the sense amplifier 33C, respectively, on, the basis of the division refresh enable signal BPE and the refresh bank control signal BC. Simultaneously, the bank enable switch circuit (MUXB) 294 outputs the row address enable signal RE5 and the sense enable signal sE5 to the row decoder 31E of the bank 32E corresponding to the bank address data BAdd and the sense amplifier 33E, respectively, on the basis of the division refresh enable signal BPE and the refresh bank control signal BE.

It is assumed that the bank enable switch circuit (MUXB) 294 inputs the fourth and sixth refresh bank control signals BD, BF. In this case, the bank enable switch circuit (MUXB) 294 outputs the row address enable signal RE4 and the sense enable signal SE4 to the row decoder 31D of the bank 32D corresponding to the bank address data BAdd and the sense amplifier 33D, respectively, on the basis of the division refresh enable signal BPE and the refresh bank control signal BD. Simultaneously, the bank enable switch circuit (MUXB) 294 outputs the row address enable signal RE6 and the sense enable signal SE6 to the row decoder 31F of the bank 32F corresponding to the bank address data BAdd and the sense amplifier 33F, respectively, on the basis of the division refresh enable signal BPE and the refresh bank control signal BF.

[Operation]

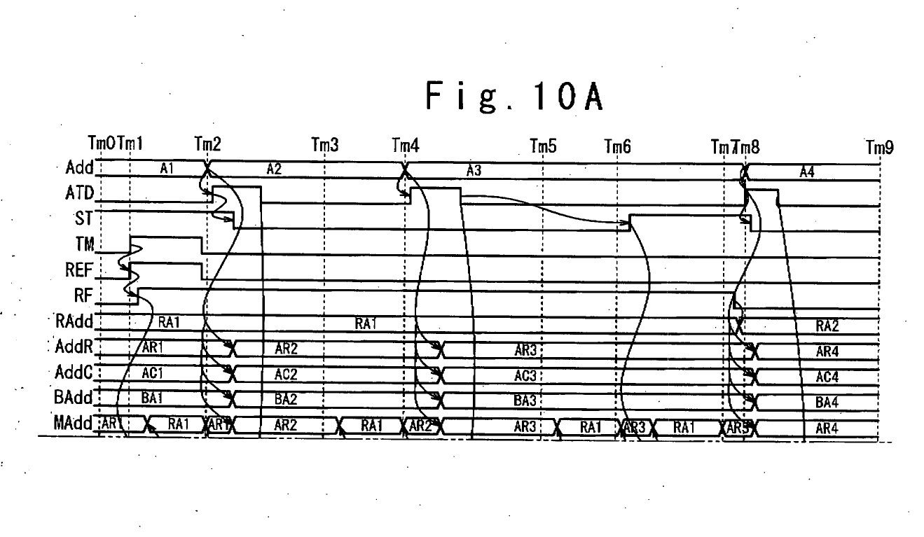

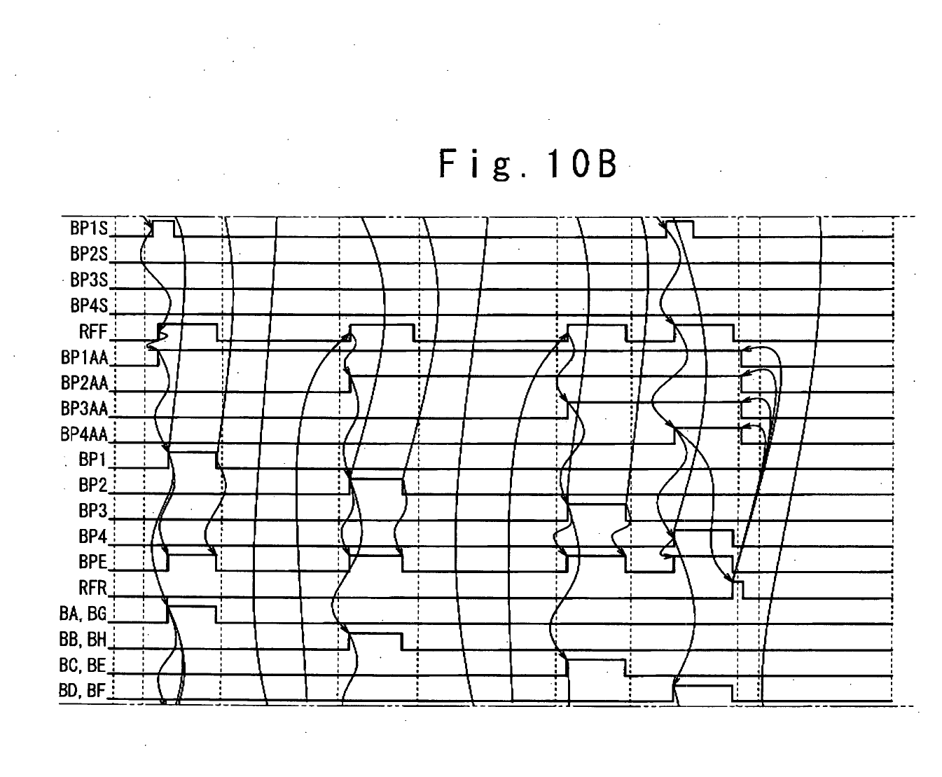

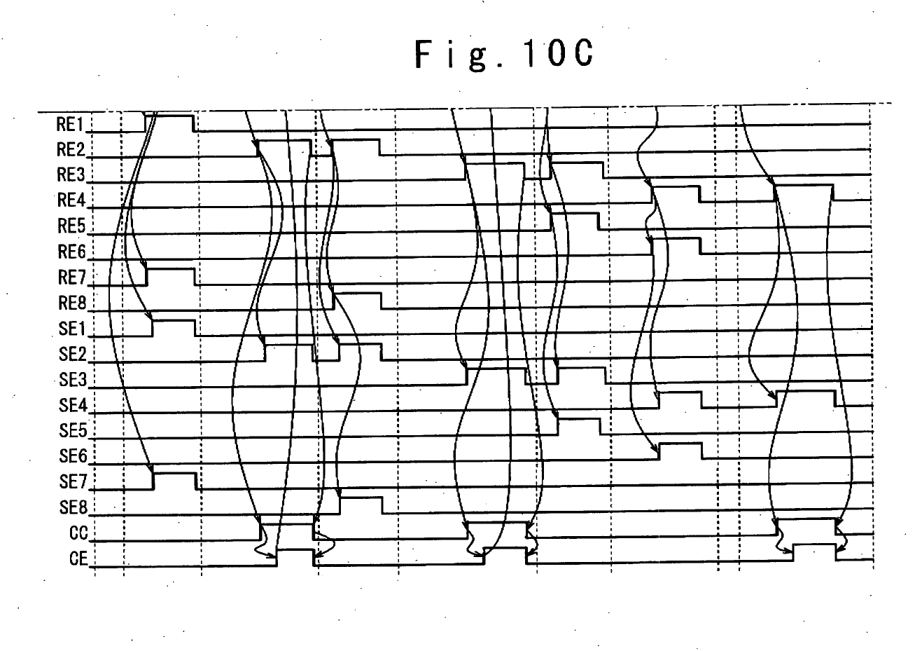

FIGS. 10A to 10C are timing charts showing the operations of the pseudo SRAM according to the first embodiment of the present invention.

The detailed description of reading and writing operations in the normal operation mode is omitted here. In this case, the operations of the reading/writing address Add, the address transition detection signal ATD, the timing signal TM, the normal refresh pulse signal REF, the refresh address RAdd, the row address data AddR, the column address data AddC, the row address MAdd, the column enable signal CE and the column control signal CC are equal to those of the conventional pseudo SRAM. The test mode entry signal TE is set to the LOW level, and the operation mode switch signal TE1 outputted by the test mode entry circuit 53 is switched to the LOW level. That is, at the normal operation mode, the test circuit is not operated. Thus, this is same to the operation of the pseudo SRAM in which the test circuit is not built.

The self, refresh operation at the normal operation mode will be described below.

At the time Tm0, the reading/writing address Add is fixed to an address data value A1 (assumed to be a value A1), and this is in the standby state and the state without any refreshing request.

Here, it is assumed that the reading/writing address Add is set to a reading/writing address data value A1 (value A1). In this case, it is assumed that, by the address buffer circuit 210, the row address data AddR is set to a row address data value AR1 (value AR1), the column address data AddC is set to a column address data value AC1 (value AC1), the bank address data BAdd is set to a bank address data value BA1 (value BA1), and the row address MAdd is set to a value AR1. Also, the refresh address RAdd is set to a refresh address data value RA1 (value RA1).

Further, the address transition detection signal ATD outputted by the ATD circuit 25 is at the LOW level, and both of the column control signal CC outputted by the row control circuit 250 and the column enable signal CE outputted by the column control circuit 27 are at the LOW level, and the standby determination signal ST outputted by the standby determination circuit 261 is at the HIGH level. Thus, the refreshing request is determined not to be still generated. Hence, the timing signal TM that is the output signal of the timer circuit 50 is at the LOW level, the normal refresh pulse signal REF that is the output signal of the refresh pulse generation circuit 60 is at the LOW level, and the refresh timing control signal RF that is the output signal of the switch circuit (MUX1S) 410 is also at the LOW level.

Thus, the standby refresh control signals BP1S to BP4S outputted by the standby refresh division circuit 260 are at the LOW level. The interruption refresh signal RFF outputted by the interruption refresh determination circuit 270 is at the LOW level. The refresh frequency signals BP1AA to BP4AA outputted by the refresh activation frequency counter 281 are at the LOW level. The refresh activation one shot signals BP1 to BP4 outputted by the refresh activation one shot circuit 282 are at the LOW level. The division refresh enable signal BPE inside the bank activation allocation circuit 290 is at the LOW level. The refresh bank control signals BA to BH outputted by the refresh bank switch circuit (MUXBR) 291 inside the bank activation allocation circuit 290 are at the LOW level. The row address enable signals. RE1 to RE8 outputted by the bank enable switch circuit (MUXB) 294 and the sense enable signals SE1 to 5E8 are at the LOW level. Both of he column control signal CC outputted by a row control circuit 2502 and the column enable signal CE outputted by the column control circuit 27 are at the LOW level.

At the time Tm1, the timer circuit 50 outputs the timing signal TM having a predetermined pulse width. At this time, the refresh pulse generation circuit 60 outputs the normal refresh pulse signal REF, as a one shot pulse signal, on the basis of the rising edge of this timing signal TM. In this case, the normal refresh pulse signal REF serves as the one shot signal of the HIGH level from the LOW level, and by the switch circuit (MUX1S) 410, the refresh timing control signal RF is switched from the LOW level to the LOW level. Then, by the standby refresh division circuit 260 in the row control circuit 250, the standby refresh control signal BP1S indicating the first refresh operation is switched from the LOW level to the HIGH level.

The standby refresh control signals BP2S to BP4S, which indicate the second to fourth refresh operations in the standby state, respectively, are at the LOW level. Thus, the interruption refresh determination circuit 270 in the row control circuit 250 switches the interruption refresh signal RFF from the LOW level to the HIGH level, in response to the HIGH level of the standby refresh control signal BP1S.

In the internal refresh division circuit 280 in the row control circuit 250, in response to the HIGH level of the interruption refresh signal RFF, by the refresh activation frequency counter 281, only the refresh frequency signal BP1AA is switched from the LOW level to the HIGH level and outputted.

The refresh frequency signal BP1AA is converted into a one shot signal in which the activation time necessary for the refresh is considered. Thus, the refresh activation one shot circuit 282 outputs the refresh activation one shot signal BP1, as the one shot signal of the HIGH level from the LOW level, in response to this refresh frequency signal BP1AA.

In the refresh bank switch circuit (MUXBR) 291 in the bank activation allocation circuit 290, in response to the refresh activation one shot signal BP1, only the refresh bank control signals BA, BG are switched to the HIGH level and outputted. All of the refresh bank control signals except the refresh bank control signals BA, BG are at the LOW level.

Also, the refresh activation one shot signal BP1 is outputted as the division refresh enable signal BPE through the NOR circuit 292 and the inverter 293 in the bank activation allocation circuit 290, and the division refresh enable signal BPE is switched from the LOW level to the HIGH level.

In the bank enable switch circuit (MUXB) 294 in the bank activation allocation circuit 290, in response to the HIGH level of the division refresh enable signal BPE, the refresh bank control signals BA, BG are made valid (at the HIGH level), and only the row address enable signals RE1, RE7 and the sense enable signals SE1, SE7 are outputted as the one shot signal of the HIGH level, with a certain time difference.

The switch circuit (MUX2S) 420 outputs the row address MAdd as the value RA1, in response to the HIGH level of the interruption refresh signal RFF.

As explained above, when the refresh timing control signal RF is supplied, the row control circuit 250 outputs the row address enable signals RE1, RE7 and the sense enable signals SE1, SE7 to the bank groups 32A, 32G, respectively, in accordance with the combination of the bank simultaneous activations and the activating order. In this case, in the bank groups 32A, 32G, the row decoders 31A, 31G selectively activate the word lines of the memory cell arrays 30A, 30G, in response to the row address enable signals RE1, RE7, respectively. The sense amplifiers 33A, 33G activate the bit lines of the memory cell arrays 30A, 30G, in response to the sense enable signals SE1, SE7, respectively. In this way, only the memory cells arranged in the banks 32A, 32G in the memory cell array unit 300 carry out the refresh operation.

At the time Tm2, the interruption refresh signal RFF is once switched to the LOW level. Thus, the value of the row address MAdd becomes the value AR1, and the reading/writing address Add is updated from the value A1 to a new address data value A2 (value A2).

Here, by the address buffer circuit 210, the row address data AddR is updated to a row address data value AR2 (value AR2), the column address data AddC is updated to a column address data value AC2 (value AC2), and the bank address data BAdd is updated to a bank address data value BA2 (value BA2).

Also, the address transition detection signal ATD outputted by the ATD circuit 25 is changed to the HIGH level from the LOW level, as the one shot signal.

The column control signal CC outputted by the row control circuit 250, the column enable signal CE outputted by the column control circuit 27, and the control of the column decoder 35 are similar to those of the conventional pseudo SRAM. Thus, their descriptions are omitted.

In the row control circuit 250, when the address transition detection signal ATD is changed to the HIGH level from the LOW level as the one shot signal, the standby determination circuit 261 in the standby refresh division circuit 260 switches the standby determination signal ST from the HIGH level to the LOW level. That is, the standby refresh division circuit 260 determines that a next operation is in the reading/writing state. At this time, the standby refresh control signals BP1S to BP4S autonomously outputted on and after the second time are held at the LOW level. In this case, in the interruption refresh determination circuit 270, until the completion of the reading/writing operation, the interruption refresh signal RFF is held at the LOW level. However, since the divided/allocated bank still indicate the state in the course of the refresh, the refresh enable signal RF is held at the HIGH level.

Since the division refresh enable signal BPE is at the LOW level, the bank enable switch circuit (MUXB) 294 in the row control circuit 250 switches only the row address enable signal RE2 and the sense enable signal SE2 to the HIGH level from the LOW level with a certain time difference, on the basis of the value BA2 of the bank address data BAdd set in accordance with the reading/writing address Add. At this time, the bank enable switch circuit (MUXB) 294 in the row control circuit 250 outputs the row address enable signal RE2 as the column enable signal CC to the column control circuit 27. In this case, since the column enable signal CC outputted by the row control circuit 250 is switched to the HIGH level from the LOW level, the column enable signal CE outputted by the column control circuit 27 is switched to the HIGH level from the LOW level. Then, the reading/writing from/to the expected bank 32B in the memory cell array unit 300 is started.

When the row address enable signal RE2 and the sense enable signal SE2 are switched to the LOW level from the HIGH level, the LOW level of the row address enable signal RE2 causes the column enable signal CC in the row control circuit 250 to be switched to the LOW level from the HIGH level. Thus, the column enable signal CE is also switched to the LOW level from the HIGH level. Then, the reading/writing operation from/to the expected address is completed.

At the time Tm3, since the refresh timing control signal RF is at the HIGH level, all of the divided/allocated banks are not still refreshed. For this reason, the time of the completion of the pre-charging of the memory cell array unit 300 is grasped to autonomously restart the inner refresh operation.

In the interruption refresh determination circuit 270, the HIGH level of the column enable signal CE is delayed by a sufficient time by its inner circuits (the delay element 271, the NAND circuit 272, the inverter 273, the NOR circuit 274 and the inverter 275) and outputted as the interruption refresh signal RFF. That is, the interruption refresh signal RFF is switched from the LOW level to the HIGH level.

The interruption refresh signal RFF is inputted to the refresh activation frequency counter 281 in the internal refresh division circuit 280. Since the refresh frequency signal BP1AA is already at the HIGH level; the refresh activation frequency counter 281 sets the refresh frequency signal BP2AA to the HIGH level. That is, this indicates the second time from the refresh operation of the standby state. The HIGH level of the refresh frequency signal BP2AA is inputted to the refresh activation one shot circuit 282. The refresh activation one shot circuit 282 outputs the refresh activation one shot signal BP2 as the one shot signal of the HIGH level from the LOW level.

The refresh bank switch circuit (MUXBR) 291 in the bank activation allocation circuit 290 outputs only the refresh bank control signals BB, BH as the one shot signal of the HIGH level, in response to the refresh activation one shot signal BP2. All of the refresh bank control signals except the refresh bank control signals BB, BH are at the LOW level.

Also, the refresh activation one shot signal BP2 is outputted as the division refresh enable signal BPE through the NOR circuit 292 and the inverter 293 in the bank activation allocation circuit 290, and its division refresh enable signal BPE is switched from the LOW level to the HIGH level.

In the bank enable switch circuit (MUXB) 294 in the bank activation allocation circuit 290, in response to the HIGH level of the division refresh enable signal BPE, the refresh bank control signals BB, BH are made valid (at the HIGH level), and only the row address enable signals RE2, RE8 and the sense enable signals SE2, SE8 are outputted as the one shot signal of the HIGH level, under a certain time difference.

The switch circuit (MUX2S) 420 outputs the value RA1 of the refresh address RAdd as the row address MAdd, in response to the HIGH level of the interruption refresh signal RFF.

As explained above, when the refresh timing control signal RF is supplied, the row control circuit 250 outputs the row address enable signals RE2, RE8 and the sense enable signals SE2, SE8 to the bank groups 32B, 32H, respectively, in accordance with the combination of the bank simultaneous activations and the activating order. In this case, in the bank groups 32B, 32H, the row decoder 31B, 31H selectively activate the word lines of the memory cell arrays 30B, 30H, in response to the row address enable signals RE2, RE8, respectively. The sense amplifiers 33B, 33H activate the bit lines of the memory cell arrays 30B, 30H, in response to the sense enable signals SE2, SE8, respectively. In this way, only the memory cells arranged in the banks 32B, 32H in the memory cell array unit 300 carry out the refresh operation.

At the time Tm4, the reading/writing address Add is updated from the value A2 to a new address data value A3 (value A3). In this case, since the interruption refresh signal RFF is once at the LOW level, the value of the row address MAdd becomes the value AR2.

Here, by the address buffer circuit 210, the row address data AddR is updated to a row address data value AR3 (value AR3), the column address data AddC is updated to a column address data value AC3 (value AC3), and the bank address data BAdd is updated to a bank address data value BA3 (value BA3).

Further, the address transition detection signal ATD outputted by the ATD circuit 25 is changed to the HIGH level from the LOW level in as the one shot signal, and similarly to the time Tm2, the refresh enable signal RE is held at the HIGH level. Once, the autonomous inner refresh becomes in a stop state.

The difference from the time Tm2 lies in the followings. The bank enable switch circuit (MUXB) 294 in the row control circuit 250 outputs only the row address enable signal RE3 and the sense enable signal SE3, as the one shot signal of the HIGH level from the LOW level under a certain time difference, in accordance with the value BA3 of the bank address data BAdd set on the basis of the reading/writing address Add, when the division refresh enable signal BPE is at the LOW level. Further, the switch circuit (MUX2S) 420 outputs the value AR3 of the row address data AddR as the row address MAdd, in response to the LOW level of the interruption refresh signal REF.

Then, since the column enable signal CE outputted by the column control circuit 27 is switched to the HIGH level from the LOW level, the reading/writing from/to the expected bank 32C in the memory cell array unit 300 is started.

When the row address enable signal RE3 and the sense enable signal SE3 are switched from the HIGH level to the LOW level, the row address enable signal RE3 becomes the Low level state. Further, at this time, the bank enable switch circuit (MUXB) 294 in the row control circuit 250 outputs the row address enable signal RE3 as the column enable signal CC to the column control circuit 27. In this case, since the column enable signal CC outputted by the row control circuit 250 is also switched from the HIGH level to the LOW level, the column enable signal CE is also switched from the HIGH level to the LOW level. Then, the reading/writing operation from/to the expected address is completed.

Thus, the reading/writing operation from/to the expected address is completed.

At the time Tm5, the refresh timing control signal RF is at the HIGH level, similarly to the time Tm3. Thus, the divided/allocated bank is still in the course of the refresh. Hence, while the pre-charging action of the memory cell array unit 300 has the sufficient time for the completion, the autonomous refresh operation is restarted similarly to the time Tm3.

The difference from the time Tm3 lies in the followings. Receiving the output of the delay element 271, the interruption refresh signal RFF is switched from the LOW level to the HIGH level. Then, when it is inputted to the refresh activation frequency counter in the internal refresh division circuit 280, because the refresh frequency signals BP1AA, BP2AA are already at the HIGH level, the refresh frequency signal BP3AA is switched to the HIGH level. That is, this indicates the third time from the refresh operation of the standby state. The HIGH level of the refresh frequency signal BP3AA is inputted to the refresh activation one shot circuit 282, and the refresh activation one shot signal BP3 is outputted as the one shot signal of the HIGH level from the LOW level.

The refresh bank switch circuit (MUXBR) 291 in the bank activation allocation circuit 290 outputs only the refresh bank control signals BC, BE as the one shot signal of the HIGH level, in response to the refresh activation one shot signal BP3. All of the refresh bank control signals except the refresh bank control signals BC, BE are at the LOW level.

Further, the refresh activation one shot signal BP3 is outputted as the division refresh enable signal BPE through the NOR circuit 292 and the inverter 293 in the bank activation allocation circuit 290, and its division refresh enable signal BPE is switched from the LOW level to the HIGH level.

In the bank enable switch circuit (MUXB) 294 in the bank activation allocation circuit 290, in response to the HIGH level of the division refresh enable signal BPE, the refresh bank control signals BC, BE are made valid (at the HIGH level), and only the row address enable signals RE3, RE5 and the sense enable signals SE3, SE5 are outputted as the one shot signal of the HIGH level under a certain time difference.

As mentioned above, when the refresh timing control signal RF is supplied, the row control circuit 250 outputs the row address enable signals RE3, RE5 and the sense enable signals SE3, SE5 to the bank groups 32C, 32E, respectively, in accordance with the combination of the bank simultaneous activations and the activating order. In this case, in the bank groups 32C, 32E, the row decoders 31C, 31E selectively activate the word lines of the memory cell arrays 30C, 30E, in response to the row address enable signals RE3, RE5, respectively. The sense amplifiers 33C, 33E activate the bit lines of the memory cell arrays 30C, 30E, in response to the sense enable signals SE3, SE5, respectively. In this way, only the memory cells arranged in the banks 32C, 32E in the memory cell array unit 300 carry out the refresh operation.

At the time Tm6, the interruption refresh signal RFF is once at the LOW level. Thus, the value of the row address MAdd is the value AR3.

When the reading/writing address Add is fixed to the value A3 and then a certain time elapses, the standby refresh division circuit 260 in the row control circuit 250 performs the determination of the standby state. Since the refresh timing control signal RF is still in the HIGH level state, the divided/allocated bank is determined not to be still refreshed, and only the standby refresh control signal BP1S indicating the first refresh operation of the standby state is set as the one shot signal of the HIGH level from the LOW level.

The standby refresh control signals BP25 to BP4S indicating the second to fourth refresh operations of the standby state are at the LOW level.

Then, similarly to the time Tm2, the interruption refresh determination circuit 270 in the row control circuit 250 outputs the interruption refresh signal RFF, as the one shot signal of the HIGH level from the LOW level, to the non-refreshed bank.

The switch circuit (MUX2S) 420 outputs the value RA1 of the refresh address RAdd as the row address MAdd, in response to the HIGH level of the interruption refresh signal RFF.

When the interruption refresh signal RFF is inputted to the refresh activation frequency counter in the internal refresh division circuit 280, the refresh frequency signal BP4AA is switched from the LOW level to the HIGH level, because the refresh frequency signals BP1AA, BP2AA and BP3AA are already at the HIGH level.

That is, this indicates the fourth time from the refresh operation of the standby state. The refresh activation one shot circuit 282 outputs the refresh activation one shot signal BP4 as the one shot signal of the HIGH level from the LOW level, in response to the HIGH level of the refresh frequency signal BP4AA.

The refresh bank switch circuit (MUXBR) 291 in the bank activation allocation circuit 290 outputs only the refresh bank control signals BD, BF as the one shot signal of the HIGH level, in response to the refresh activation one shot signal BP4. All of the refresh bank control signals except the refresh bank control signals BD, BF are at the LOW level.

Also, the refresh activation one shot signal BP4 is outputted as the division refresh enable signal BPE through the NOR circuit 292 and the inverter 293 in the bank activation allocation circuit 290, and its division refresh enable signal BPE is switched from the LOW level to the HIGH level.

In the bank enable switch circuit (MUXB) 294, in accordance with the HIGH level period of the division refresh enable signal BPE, the refresh bank control signals BD, BF are made valid (at the HIGH level), and only the row address enable signals RE4, RE6 and the sense enable signals SE4, SE6 are outputted as the one shot signal of the HIGH level under a certain time difference.

As mentioned above, when the refresh timing control signal RF is supplied, the row control circuit 250 outputs the row address enable signals RE4, RE6 and the sense enable signals SE4, SE6 to the bank groups 32D, 32F, respectively, in accordance with the combination of the bank simultaneous activations and the activating order. In this case, in the bank groups 32D, 32F, the row decoder 31D, 31F selectively activate the word lines of the memory cell arrays 30D, 30F, in response to the row address enable signals RE4, RE6, respectively. The sense amplifiers 33D, 33F activate the bit lines of the memory cell arrays 30D, 30F, in response to the sense enable signals SE4, SE6, respectively. In this way, only the memory cells arranged in the banks 32D, 32F in the memory cell array unit 300 carry out the refresh operation.

At the time Tm7, the interruption refresh signal RFF is once at the LOW level. Thus, the row address MAdd has the value AR3.

In the internal refresh division circuit 280 in the row control circuit 250, all of the refresh frequency signals BP1AA to BP4AA outputted by the refresh activation frequency counter 281 are switched to the HIGH level.

In short, the refresh operations until the refresh operation interrupted in the course of the reading/writing operation of the time Tm6 from the first refresh operation in the standby state at the time Tm1 indicate that all of the refresh operations corresponding to the eight banks in the memory cell array unit 300 are executed.

Then, the refresh frequency signals BP1AA to BP4AA are outputted as the refresh frequency counter reset signal RFR through the NAND circuit 283, the inverter 284, the delay element 285 and the delay element 286, after the waiting for a certain time. At that time, the refresh frequency counter reset signal RFR serves as the one shot signal of the HIGH level from the LOW level, and this is inputted to the refresh activation frequency counter 281, the switch circuit (MUX1S) 410 and the refresh address generation circuit 660. When all of the refresh frequency signals BP1AA to BP4AA are at the HIGH level, the refresh activation frequency counter 281 resets their refresh frequency signals BP1AA to BP4AA to the LOW level.

Further, in the switch circuit MUX 141, in response to the one shot signal of the HIGH level from the LOW level that serves as the refresh frequency counter reset signal RFR, the refresh timing control signal RF is switched from the HIGH level to the LOW level.

The refresh address generation circuit 660 updates the refresh address RAdd from the value RA1 to the refresh address data value RA2 (value RA2).

At the time Tm8, the interruption refresh signal RFF is once at the LOW level. Thus, the value of the row address MAdd is the value AR3.

Then, the reading/writing address Add is updated from the value A3 to a new address data value A4 (value A4).

Here, by the address buffer circuit 210, the row address data AddR is updated to a row address data value AR4 (value AR4), the column address data AddC is updated to a column address data value AC4 (value AC4), and the bank address data BAdd is updated to a bank address data value BA4 (value BA4).

The address transition detection signal ATD outputted by the ATD circuit 25 is changed to the HIGH level from the LOW level in the one shot signal.

At the time Tm7, all of the refreshes of the divided/allocated banks are completed, and the refresh timing control signal RF indicating that there is no refreshing request is switched to the LOW level. In this case, the interruption refresh signal RFF outputted by the refresh determination circuit 270 is fixed to the LOW level. At this time, the switch circuit (MUX2S) 420 outputs the row address MAdd as the value AR4, in response to the LOW level of the interruption refresh signal RFF.

Similarly to the time Tm3 and the time Tm5, and the reading/writing operation is started, the division refresh enable signal BPE is at the LOW level at this time. Thus, the bank enable switch circuit (MUXB) 294 outputs only the row address enable signal RE4 and the sense enable signal SE4, as the one shot signal of the HIGH level from the LOW level, under a certain time difference, because the bank address data BAdd has the value BA4.

The column enable signal CC in the row control circuit 250 is switched from the LOW level to the HIGH level. In this case, the column enable signal CE outputted by the column control circuit 27 is switched from the LOW level to the HIGH level, and the reading/writing from/to the bank 32D in the memory cell unit 300 is started. At this time, when the column enable signal CE is switched from the HIGH level to the LOW level and also the row address enable signal RE4 and the sense enable signal SE4 are switched from the HIGH level to the LOW level, the reading/writing operation from/to the expected address is completed.

At the time Tm9, there is no update of the reading/writing address Add, and the refresh timing control signal RF is at the LOW level. Thus, this is the state that the reading/writing operation and the refresh operation, in which the reading/writing address Add is fixed, are finished, and this has the same standby state as the time Tm0.

The activation combinations of the plurality of banks arranged in the memory cell array unit 300 can be arbitrarily combined.

As explained above, in the pseudo SRAM according to the first embodiment of the present invention, the row control circuit 250 outputs the row address enable signals (RE1, RE7) (RE2, RE8) (RE3, RE5) and (RE4, RE6) and the sense enable signals (SE1, SE7) (SE2, SE8) (SE3, SE5) and (SE4, SE6) to the bank groups (32A, 32G) (32B, 32H) (32C, 32E) and (32D, 32F), in accordance with the combination of the bank simultaneous activations and the activating order, when the refresh timing control signal RF is supplied.

Specifically, in the row control circuit 250, the standby refresh division circuit 260 monitors whether or not the reading/writing operation is executed when the refresh timing control signal RF “HIGH level” is supplied, and outputs the standby refresh control signals BP1S to BP4S indicating its monitored result. When the refresh timing control signal RF “HIGH level” is supplied and the standby refresh control signals BP1S to BP4S do not indicate the execution of the reading/writing operation, the interruption refresh determination circuit 270 outputs the interruption refreshing signal RFF to execute the refresh operation. The refresh activation frequency-counter 281 inside the internal refresh division circuit 280 counts a frequency Z (Z is an integer satisfying 1≦Z≦Y, and Y is 4) of the supplies of the interruption refreshing signal RFF. The refresh activation one shot circuit 282 outputs the refresh activation one shot signals BP1 to BP4 indicating its counted value. Here, the refresh activation frequency counter 281 is reset after a predetermined time, when the counted value is Y (Y=4). The bank activation allocation circuit (290) outputs the row address enable signal and the sense enable signal to the bank group of a Z-th group, which corresponds to the counted value indicated by the refresh activation one shot signals BP1 to BP4, among the bank groups of the four groups such as (32A, 32G) (32B, 32H) (32C, 32E) and (32D, 32F), in accordance with the combination of the bank simultaneous activations and the activating order. When the respective refresh activation one shot signals BP1 to BP4 are at the HIGH level, the respective counted values indicate 1, 2, 3 and 4.

Here, in the refresh bank switch circuit (MUXBR) 291 inside the bank activation allocation circuit (290), with regard to the banks 32A to 32H in the M rows N columns, the bank groups each composed of {the two banks (32A, 32G) (32B, 32H) (32C, 32E) or (32D 32F)} as the combination of the bank simultaneous activations is allocated to each of the four groups composed of the first to fourth groups as the activating order. The bank enable switch circuit (MUXB) 294 outputs the row address enable signals (RE1, RE7) (RE2, RE8) (RE3, RE5) and (RE4, RE6) and the sense enable signals (SE1, SE7) (SE2, SE8) (SE3, SE5) and (SE4, SE6) to the bank groups of the four groups such as (32A, 32G) (32B, 32H) (32C, 32E) and (32D 32F), from the first group to the fourth group in this order, in accordance with the combination of the bank simultaneous activations and the activating order.

### [Effect]

In this way, in the pseudo SRAM according to the first embodiment of the present invention, it is determined whether or not the operation is in the course of the writing/reading operation and the standby state, and in accordance with the combination of the bank simultaneous activations and the activating order, the control of the interruption while allocating to the subsequent writing/reading operation and the standby state is carried out. Thus, in the pseudo SRAM according to the first embodiment of the present invention, while the peak current of one refresh operation is reduced to ¼ of the conventional technique, the interference between adjacent banks can be avoided. Moreover, the autonomous refresh operation can be carried out at a minimum cycle of the writing/reading operation.

Thus, in the pseudo SRAM whose capacity is made large by employing the many-bank configuration, it is possible to avoid the simultaneous activation between the plurality of adjacent banks, disperse the peak current and suppress the interferences such as the drop in the internal power source and the floating of GND, in the internal power source wirings and GND wirings inside the memory cell array unit 300 that are laid in near region on layout. Thus, the sense amplifier inside the memory cell array unit 300 can obtain the supply of the level sufficient for a driving signal and can sufficiently enlarge the potential of the Digit (bit line) pair within the activation time of the word line. Hence, the holding level of the memory cell data can be sufficiently obtained, thereby solving the lack of the data hold time of the memory cell. In this way, in the present embodiment, the data break in the memory cell that is caused by the lack of the data hold time can be prevented in the pseudo SRAM of the large capacity that is provided with the many banks.

Further, in the pseudo SRAM according to the first embodiment of the present invention, whether or not the interruption refreshing request is in the course of the writing/reading operation and in the standby state is determined, and one combination of the bank activations as divided above is allocated as the component corresponding to one cycle of the refresh operation in the subsequent writing/reading operation cycle and the standby state. Thus, it is possible to suppress the extension of the cycle of the writing/reading operation caused by the interruption refresh peculiar to the pseudo SRAM.

### Second Embodiment

### Configuration

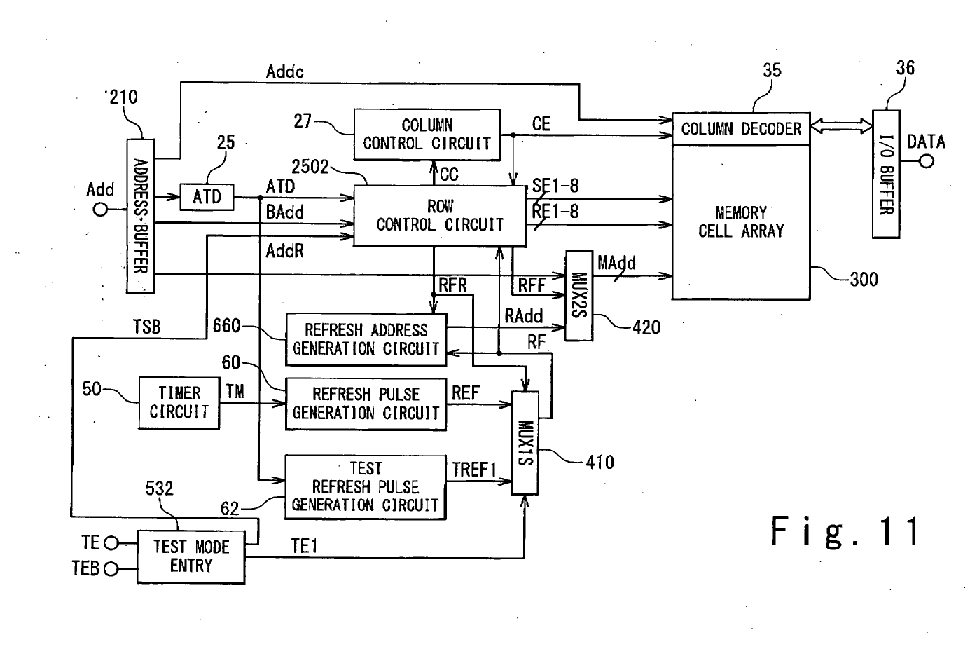

FIG. 11 is a block diagram showing the configuration of the pseudo SRAM according to the second embodiment of the present invention.

The pseudo SRAM according to the second embodiment of the present invention contains a row control circuit 2502 and a test mode entry circuit 532, instead of the row control circuit 250 and the test mode entry circuit 53 in the first embodiment. In the second embodiment, the descriptions overlapping with those of the first embodiment are omitted.

When a bank selection test mode entry signal TEB is given from outside, the test mode entry circuit 532 outputs the bank selection test mode entry signal TEB as a bank selection mode signal TSB to the row control circuit 2502, independently of a test mode entry signal TE.

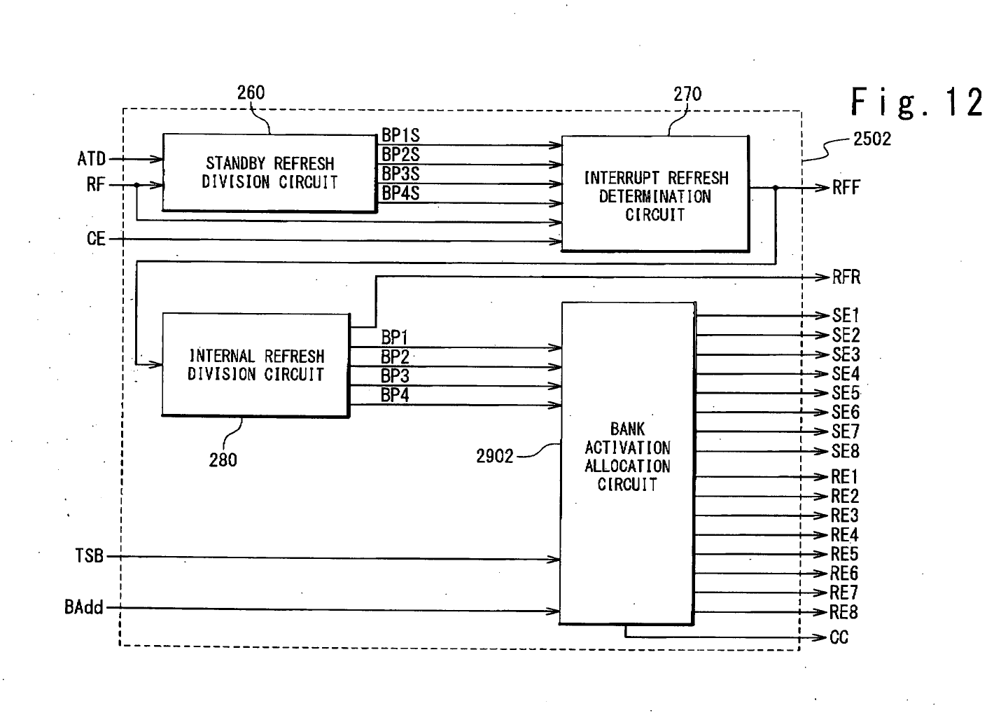

FIG. 12 shows the configuration of the row control circuit 2502 in FIG. 11.

The row control circuit 2502 contains a bank activation allocation circuit 2902, instead of the bank activation allocation circuit 290. Further, the bank activation allocation circuit 2902 is connected to the output of the test mode entry circuit 532, and inputs the bank selection mode signal TSB outputted by the test mode entry circuit 532.

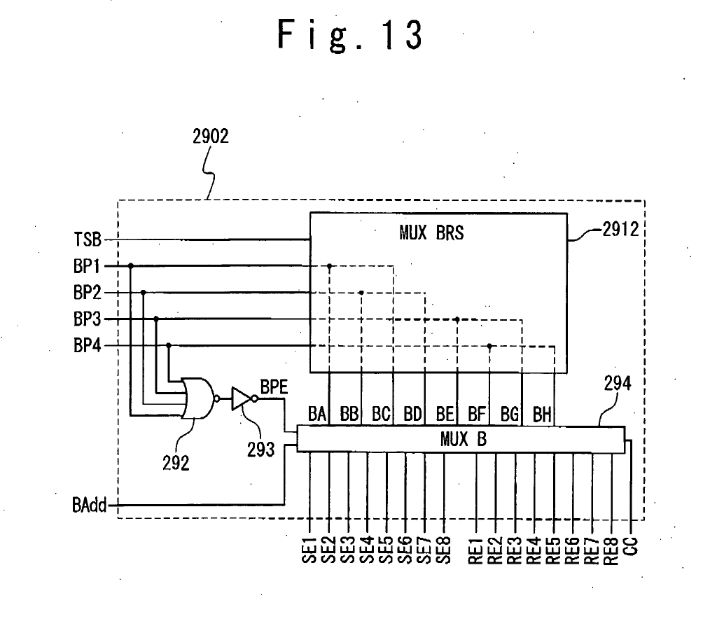

FIG. 13 shows the configuration of the bank activation allocation circuit 2902 in FIG. 12.

The bank activation allocation circuit 2902 contains a refresh bank switch circuit (MUXBRS) 2912, instead of the refresh bank switch circuit (MUXBR) 291 in the first embodiment.

The refresh bank switch circuit (MUXBRS) 2912 outputs the above refresh bank control signals BA to BH as a combination, which will be described later, to the bank enable switch circuit (MUXB) 294, in response to the bank selection mode signal TSB and the refresh activation one shot signals BP1 to BP4.

FIG. 17 shows the combination of the bank simultaneous activations and the activating order, in the pseudo SRAM according to the second embodiment of the present invention.

As, shown in FIG. 17, the combination of the bank simultaneous activations and the activating order can be changed by setting the bank selection test mode entry signal TEB. The bank selection test mode entry signal TEB is used to avoid the simultaneous activation between the adjacent banks by employing a combination different from that of the first embodiment. Further, the refreshing order of the combinations can be determined in order to perform the allocation and the interruption in the course of the writing/reading operation and the standby state.

An example of the combination of the bank simultaneous activations and the activating order will be described below. When the bank groups of Y (Y=4) groups such as (32A, 32G) (32B, 32H) (32C, 32E) and (32D, 32F) are assumed to be the bank groups of the four groups such as (32A, 32G) (32B, 32H) (32C, 32E) and (32D, 32F) based on a first specification, the bank groups of four groups such as (32A, 32C) (32B, 32D) (32E, 32G) and (32F, 32H) based on a second specification which differs from the first specification with regard to the combination of the bank simultaneous activations and the activating order are further allocated to the refresh bank switch circuit (MUXBR) 291.

That is, the combination of the bank simultaneous activations and the activating order in the first specification are defined as the banks 32A, 32G in the first group, the banks 32B, 32H in the second group, the banks 32C, 32E in the third group, and the banks 32D, 32F in the fourth group. On the other hand, differently from the first specification, the combination of the bank simultaneous activations and the activating order in the second specification are defined as the banks 32A, 32C in the first group, the banks 32B, 32D in the second group, the banks 32E, 32G in the third group, and the banks 32F, 32H in the fourth group.

As the above combination, the refresh bank switch circuit (MUXBR) 291 outputs the refresh bank control signals BA, BC to the bank enable switch circuit (MUXB) 294, in response to the refresh activation one shot signal BP1. The refresh bank switch circuit (MUXBR) 291 outputs the refresh bank control signals BB, BD to the bank enable switch circuit (MUXB) 294, in response to the refresh activation one shot signal BP2. The refresh bank switch circuit (MUXBR) 291 outputs the refresh bank control signals BE, BG to the bank enable switch circuit (MUXB) 294, in response to the refresh activation one shot signal BP3. The refresh bank switch circuit (MUXBR) 291 outputs the refresh bank control signals BF, BH to the bank enable switch circuit (MUXB) 294, in response to the refresh activation one shot signal BP4.

### [Operation]

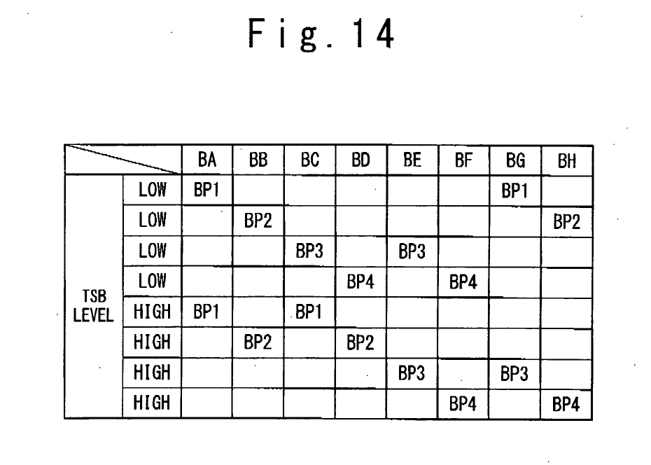

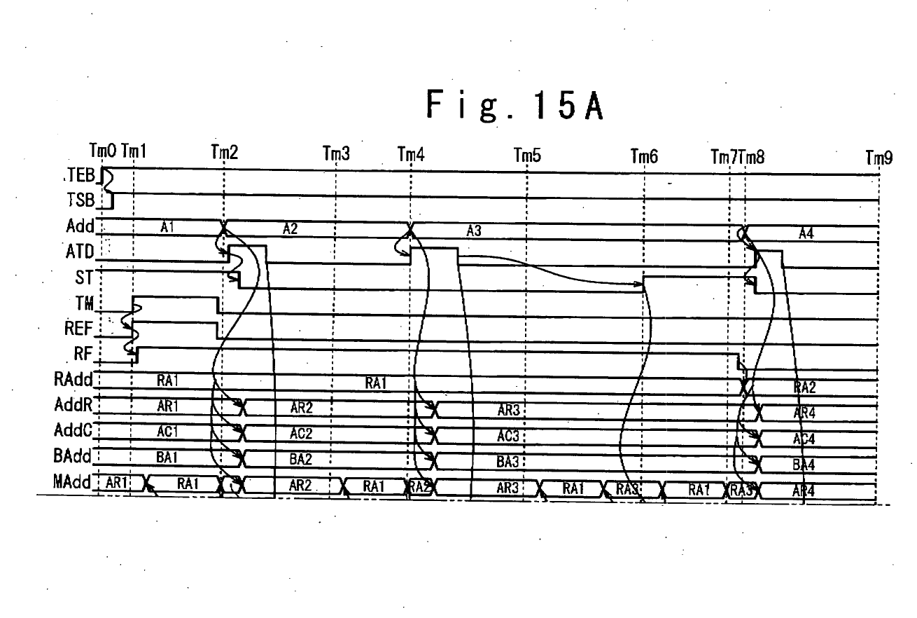

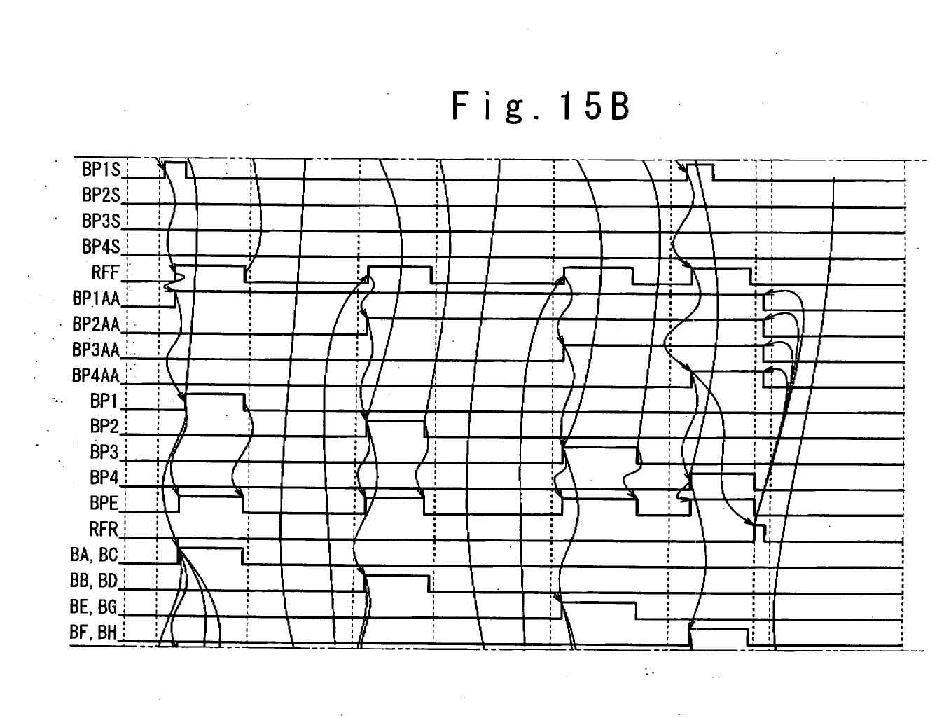

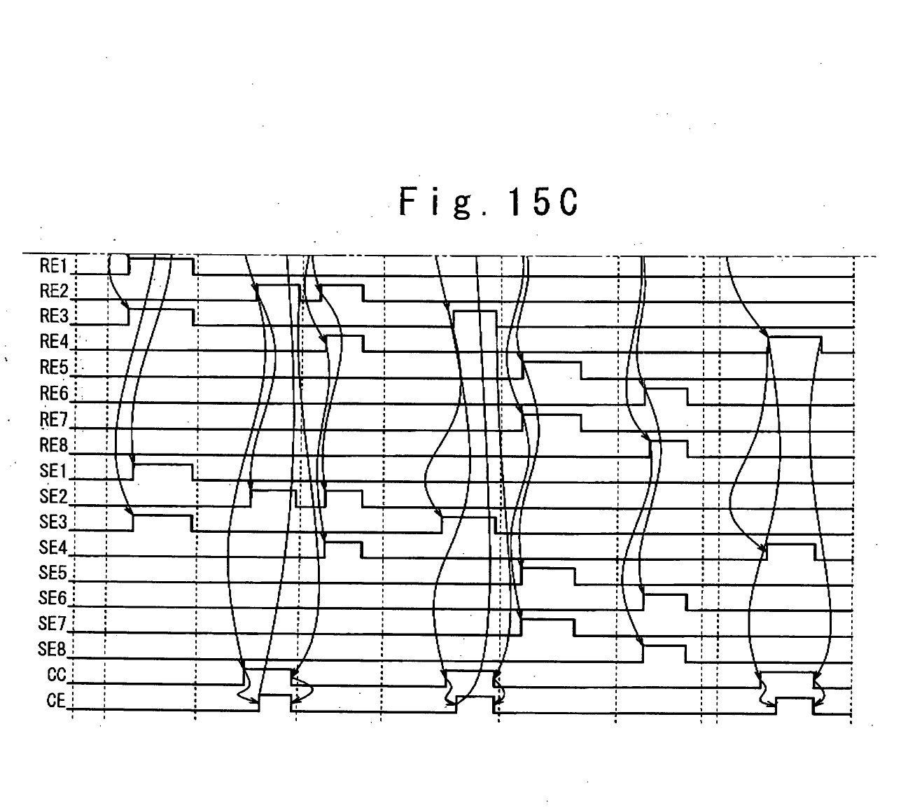

FIG. 14 shows a state diagram of the bank activation allocation circuit in the pseudo SRAM according to the second embodiment of the present invention. FIGS. 15A to 15C are timing charts showing the operations in the pseudo SRAM according to the second embodiment of the present invention.

The second embodiment (refer to FIGS. 15A to 15C) differs from the first embodiment (refer to FIGS. 10A to 10C) in that at the time Tm0, the bank selection test mode entry signal TEB is switched to the HIGH level, and the bank selection mode signal TSB outputted by the test mode entry circuit 532 is switched to the HIGH level.

The case in which at the time Tm0, the bank selection test mode entry signal TEB is at the LOW level is equal to the case of the first embodiment. Thus, its description will be omitted below.

The difference between the time Tm1 of the second embodiment and the time Tm1 of the first embodiment will be described below.

Since the bank selection mode signal TSB is at the HIGH level, the refresh bank switch circuit (MUXBRS) 2912 in the bank activation allocation circuit 2902 determines the combination of the bank simultaneous activations and the activating order, in the interruption refresh operation, as shown in FIG. 14.

The refresh bank switch circuit (MUXBRS) 2912 switches only the refresh bank control signals BA, BC to the HIGH level, in response to the refresh activation one shot signal BP1, and outputs them. All of the refresh bank control signals except the refresh bank control signals BA, BC are at the LOW level.

In this case, the refresh activation one shot signal BP1 is outputted as the division refresh enable signal BPE through the NOR circuit 292 and the inverter 293, and the division refresh enable signal BPE is switched to the HIGH level. In the bank enable switch circuit (MUXB) 294, in a period in which the level of the division refresh enable signal BPE is at the HIGH level, the refresh bank control signals BA, BC are made valid (at the HIGH level), and only the row address enable signals RE1, RE3 and the sense enable signals SE1, SE3 are outputted as the one shot signal of the HIGH level, under a certain time difference.

By the operation described above, only the memory cells arranged in the banks 32A, 32C in the memory cell array unit 300 are targeted for the refresh operation.

The difference between the time Tm3 of the second embodiment and the time Tm3 of the first embodiment will be described below.

The refresh bank switch circuit (MUXBRS) 2912 switches only the refresh bank control signals BB, BD to the HIGH level, in response to the refresh activation one shot signal BP2 and outputs them. All of the refresh bank control signals except the refresh bank control signals BB, BD are at the LOW level.

In this case, the refresh activation one shot signal BP2 is outputted as the division refresh enable signal BPE through the NOR circuit 292 and the inverter 293, and the division refresh enable signal BPE is switched to the HIGH level. In the bank enable switch circuit (MUXB) 294, in the period in which the level of the division refresh enable signal BPE is at the HIGH level, the refresh bank control signals BB, BD are made valid (at the HIGH level), and only the row address enable signals RE2, RE4 and the sense enable signals SE2, SE4 are outputted as the one shot signal of the HIGH level, under a certain time difference.

By the operation described above, only the memory cells arranged in the banks 32B, 32D in the memory cell array unit 300 are targeted for the refresh operation.

The difference between the time Tm5 of the second embodiment and the time Tm5 of the first embodiment will be described below.

The refresh bank switch circuit (MUXBRS) 2912 switches only the refresh bank control signals BE, BG to the HIGH level, in response to the refresh activation one shot signal BP3 and outputs them. All of the refresh bank control signals except the refresh bank control signals BE, BG are at the LOW level.

In this case, the refresh activation one shot signal BP3 is outputted as the division refresh enable signal BPE through the NOR circuit 292 and the inverter 293, and the division refresh enable signal BPE is switched to the HIGH level. In the bank enable switch circuit (MUXB) 294, in the period in which the level of the division refresh enable signal BPE is at the HIGH level, the refresh bank control signals BE, BG are made valid (at the HIGH level), and only the row address enable signals RE5, RE7 and the sense enable signals SE5, SE7 are outputted as the one shot signal of the HIGH level, under a certain time difference.

By the operation described above, only the memory cells arranged in the banks 32E, 32G in the memory cell array unit 300 are targeted for the refresh operation.

The difference between the time Tm6 of the second embodiment and the time Tm6 of the first embodiment will be described below.

The refresh bank switch circuit (MUXBRS) 2912 switches only the refresh bank control signals BF, BH to the HIGH level, in response to the refresh activation one shot signal BP4 and outputs them. All of the refresh bank control signals except the refresh bank control signals BF, BH are at the LOW level.

In this case, the refresh activation one shot signal BP4 is outputted as the division refresh enable signal BPE through the NOR circuit 292 and the inverter 293, and the division refresh enable signal BPE is switched to the HIGH level. In the bank enable switch circuit (MUXB) 294, in the period in which the level of the division refresh enable signal BPE is at the HIGH level, the refresh bank control signals BF, BH are made valid (at the HIGH level), and only the row address enable signals RE6, RE8 and the sense enable signals SE6, SE8 are outputted as the one shot signal of the HIGH level, under a certain time difference.

By the operation described above, only the memory cells arranged in the banks 32F, 32H in the memory cell array unit 300 are targeted for the refresh operation.

The operations on and after the time Tm7 are equal to those of the first embodiment.

As mentioned above, in the pseudo SRAM according to the second embodiment of the present invention, when the bank groups of the four groups such as (32A, 32G) (32B, 32H) (32C, 32E) and (32D, 32F) are assumed to be the bank groups of the four groups such as (32A, 32G) (32B, 32H) (32C, 32E) and (32D, 32F) based on the first specification, the bank groups of the four groups such as (32A, 32C) (32B, 32D) (32E, 32G) and (32F, 32H) based on the second specification which differs from the first specification with regard to the combination of the bank simultaneous activations and the activating order are further allocated to the refresh bank switch circuit (MUXBR) 2912 inside the bank activation allocation circuit (2902). When the bank selection test mode entry signal TEB is not supplied to the refresh bank switch circuit (MUXBR) 2912, the bank enable switch circuit (MUXB) 294 outputs the row address enable signals (RE1, RE7) (RE2, RE8) (RE3, RE5) and (RE4, RE6) and the sense enable signals (SE1, SE7) (SE2, SE8) (SE3, SE5) and (SE4, SE6) to the bank groups of the Y groups based on the first specification, such as (32A, 32G) (32B, 32H) (32C, 32E) and (32D, 32F), from the first group to the fourth group in this order, in accordance with the combination of the bank simultaneous activations and the activating order. When the bank selection test mode entry signal TEB is supplied to the refresh bank switch circuit (MUXBR) 2912, the bank enable switch circuit (MUXB) 294 outputs the row address enable signals (RE1, RE3) (RE2, RE4) (RE5, RE7) and (RE6, RE8) and the sense enable signals (SE1, SE3) (SE2, SE4) (SE5, SE7) and (SE6, SE8) to the bank groups of the four groups based on the second specification, such as (32A, 32C) (32B, 32D) (32E, 32G) and (32F, 32H), from the first group to the fourth group in this order, in accordance with the combination of the bank simultaneous activations and the activating order.

### [Effect]

In this way, in the pseudo SRAM according to the second embodiment of the present invention, by setting the bank selection test mode (at which the bank selection test mode entry signal TEB is at the HIGH level), it is possible to change the activation combination and activating order of the banks in the interruption refresh operation in the course of the writing/reading operation and in the standby state. Thus, in the pseudo SRAM according to the second embodiment of the present invention, in addition to the effects of the first embodiment, under the control of the interruption refresh operation in the first embodiment, when there is a trouble in the operational margin of the refresh, even after the pseudo SRAM is produced, by setting the bank selection test mode, it is possible to easily change the different activation combination and activating order of the banks, and the refresh operation enables the optimal activation combination and activating order of the banks to be acquired.

Although the present invention has been described above in connection with several embodiments thereof, it would be apparent to those skilled in the art that those exemplary embodiments are provided solely for illustrating the present invention, and should not be relied upon to construe the appended claims in a limiting sense.

What is claimed is:

1. A semiconductor storage device comprising;
a memory cell array part including a plurality of banks;
a refresh control circuit configured to output a refresh timing control signal periodically; and
an access control circuit configured to perform a refresh operation on a group of banks which are not adjacent to one another in accordance with a preset combination of banks which are simultaneously activated and a preset activating order when the refresh timing control signal is supplied.

2. The semiconductor storage device according to claim 1, wherein the access control circuit comprises a row control circuit configured to output a row address enable signal and a sense enable signal to the group of banks in accordance with the preset combination of banks and the preset activating order when the refresh timing control signal is supplied,
each of the plurality of banks comprises a memory cell array, a row decoder and a sense amplifier,
the row decoder in the group of banks selectively activates a word line os the memory cell array in the group of banks in response to the row address enable signal, and
the sense amplifier in the group of banks activates a bit line of the memory cell array in the group of banks in response to the sense enable signal.

3. The semiconductor storage device according to claim 2, wherein the plurality of banks are arranged in M rows and N columns (each of M and N is an integer equal to or larger than 2 and M×N is an even number),
the row control circuit comprises a bank activation allocation circuit, and
the bank activation allocation circuit comprises:
a refresh bank switch circuit in which X number of banks being the group of banks which are simultaneously activated by the access control circuit are allocated to the plurality of banks arranged in M rows and N columns as Y number of combinations from 1st combination to Y-th combination (each of X and Y is an integer equal to or larger than 2 and satisfying X×Y=M×N) which correspond to the preset activating order, and
a bank enable switch circuit configured to output the row address enable signal and the sense enable signal to the Y number of combinations from the 1st combination to Y-th combination in order in accordance with the preset combination of banks which are simultaneously activated and the preset activating order.

4. The semiconductor storage device according to claim 3, wherein the row control circuit further comprises:
an interruption refresh determination circuit configured to output an interruption refresh signal for performing the refresh operation when reading or is performed in a period where the refresh timing control signal is supplied; and
an internal refresh division circuit configured to output a refresh activation one shot signal corresponding to a frequency Z (Z is an integer satisfying 1≦Z≦Y) indicating a frequency of a supply of the interruption refresh signal, and
the bank enable switch circuit is configured to output the row address enable signal and the sense enable signal to a bank group of a Z-th combination corresponding to the refresh activation one shot signal among the Y number of combinations in accordance with the preset combination of banks which are simultaneously activated and the preset activating order.

5. The semiconductor storage device according to claim 4, wherein the internal refresh division circuit comprises:
a refresh activation frequency counter configured to count the frequency Z indicating the frequency of the supply of the interruption refresh signal; and
a refresh activation one shot circuit configured to output a refresh activation one shot signal indicating a count value of the frequency Z, and
the bank enable switch circuit is configured to output the row address enable signal and the sense enable signal to the bank group of the Z-th combination corresponding to the count value indicated by the refresh activation one shot signal among the Y number of combinations in accordance with the preset combination of banks which are simultaneously activated and the preset activating order.

6. The semiconductor storage device according to claim 5, wherein the refresh activation frequency counter is configured to be reset after a predetermined time when the count value is Y.

7. The semiconductor storage device according to claim 4, wherein the row control circuit further comprising:
a standby refresh division circuit configured to perform monitoring whether the reading or writing is performed or not in a period where the refresh timing control signal is supplied and to output standby refresh control signal indicating a result of the monitoring, and
the interrupt refresh determination circuit is configured to output the interruption refresh signal when the standby refresh control signal does not indicate that the reading or writing is performed.

8. The semiconductor storage device according to claim 3, wherein in the refresh bank switch circuit, when the Y number of combinations are assumed to be a first specification of Y number of bank groups, a second specification of Y number of bank groups which is different from the first specification in the preset combination and the preset activating order is further allocated, and
the bank enable switch circuit is configured to:
output the row address enable signal and the sense enable signal to the first specification of Y number of combinations from the 1st combination to Y-th combination in order in accordance with the preset combination of banks which are simultaneously activated and the preset activating order when a bank selection test mode entry signal is not supplied; and
output the row address enable signal and the sense enable signal to the second specification of Y number of combinations from the 1st combination to Y-th combination in order in accordance with the preset combination of banks which are simultaneously activated and the preset activating order when the bank selection test mode entry signal is supplied.

9. The semiconductor storage device according to claim 1, wherein the refresh operation is a self-refresh operation.

10. A refresh control method of a semiconductor storage device having a memory cell array part including a plurality of banks comprising:
outputting a refresh timing control signal periodically; and
performing a refresh operation on a group of banks which are not adjacent to one another in accordance with a preset combination of banks which are simultaneously activated and a preset activating order when the refresh timing control signal is supplied.
